(19) United States
(12) Patent Application Publication
(10) Pub. No.: US 2016/0268474 A1
(43) Pub. Date: Sep. 15, 2016

(54) SEMICONDUCTOR LIGHT EMITTING DEVICE

(71) Applicant: KABUSHIKI KAISHA TOSHIBA, Tokyo (JP)

(72) Inventors: Hiroshi Katsuno, Komatsu Ishikawa (JP); Akira Ishiguro, Kanazawa Ishikawa (JP); Shinji Yamada, Nonoichi Ishikawa (JP)

(21) Appl. No.: 14/842,601

(22) Filed: Sep. 1, 2015

(30) Foreign Application Priority Data
Mar. 9, 2015 (JP) 2015-046077

(51) Int. Cl. H01L 33/20; H01L 33/38

(52) U.S. Cl. CPC H01L 33/20; H01L 33/38

(57) ABSTRACT

According to one embodiment, a semiconductor light emitting device includes a base body, first to third semiconductor layers, a first conductive layer, first and second insulating layers. The first semiconductor layer includes a region of a first conductivity type. The second semiconductor layer is provided between the first semiconductor layer and the base body, and has a second conductivity type. The third semiconductor layer is provided between the first and second semiconductor layers. The first conductive layer is provided between a part of the second semiconductor layer and the base body. The first conductive layer is electrically connected to the second semiconductor layer. The first insulating layer is provided between another part of the second semiconductor layer and the base body and between the first conductive layer and the base body. The second insulating layer is provided between the first insulating layer and the base body.

### CROSS-REFERENCE TO RELATED APPLICATIONS

This application is based upon and claims the benefit of priority from Japanese Patent Application No. 2015-046077, filed on Mar. 9, 2015; the entire contents of which are incorporated herein by reference.

### FIELD

Embodiments described herein relate generally to a semiconductor light emitting device.

### BACKGROUND

A semiconductor light emitting device such as a light emitting diode (LED) requires improvement in breakdown voltage.

### BRIEF DESCRIPTION OF THE DRAWINGS

FIG. 1A and FIG. 1B are schematic cross-sectional views illustrating a semiconductor light emitting device according to a first embodiment;

FIG. 2 is a schematic plan view illustrating the semiconductor light emitting device according to the first embodiment;

FIG. 3 is a microscope image illustrating a semiconductor light emitting device;

FIG. 4A to FIG. 4D are schematic cross-sectional views of a process order illustrating a part of a method for manufacturing the semiconductor light emitting device according to the first embodiment;

FIG. 5 is a schematic cross-sectional view illustrating a part of the semiconductor light emitting device according to the first embodiment;

FIG. 6A to FIG. 6F are schematic cross-sectional views of a process order illustrating a method for manufacturing the semiconductor light emitting device according to the first embodiment;

FIG. 7A and FIG. 7B are schematic cross-sectional views illustrating another semiconductor light emitting device according to the first embodiment;

FIG. 8A and FIG. 8B are schematic cross-sectional views illustrating a semiconductor light emitting device according to a second embodiment;

FIG. 9 is a schematic plan view illustrating the semiconductor light emitting device according to the second embodiment;

FIG. 10 is a schematic cross-sectional view illustrating the semiconductor light emitting device according to the second embodiment;

FIG. 11A and FIG. 11B are schematic cross-sectional views illustrating another semiconductor light emitting device according to the second embodiment;

FIG. 12 is a schematic cross-sectional view illustrating a semiconductor light emitting device according to the embodiment;

FIG. 13 is a schematic cross-sectional view illustrating a semiconductor light emitting device according to a third embodiment;

FIG. 14A and FIG. 14B are schematic cross-sectional views illustrating other semiconductor light emitting devices according to the third embodiment;

FIG. 15A and FIG. 15B are schematic cross-sectional views illustrating other semiconductor light emitting devices according to the third embodiment;

FIG. 16 is a schematic cross-sectional view illustrating another semiconductor light emitting device according to the third embodiment;

FIG. 17A and FIG. 17B are schematic cross-sectional views illustrating other semiconductor light emitting devices according to the third embodiment;

FIG. 18A and FIG. 18B are schematic cross-sectional views illustrating other semiconductor light emitting devices according to the third embodiment; and

FIG. 19 is a schematic cross-sectional view illustrating a semiconductor light emitting device according to a fourth embodiment.

### DETAILED DESCRIPTION

According to one embodiment, a semiconductor light emitting device includes a base body, first to third semiconductor layers, a first conductive layer, first and second insulating layers. The first semiconductor layer includes a region of a first conductivity type. The second semiconductor layer is provided between the first semiconductor layer and the base body, and has a second conductivity type. The third semiconductor layer is provided between the first semiconductor layer and the second semiconductor layer. The first conductive layer is provided between a part of the second semiconductor layer and the base body. The first conductive layer is electrically connected to the second semiconductor layer. The first insulating layer is provided between another part of the second semiconductor layer and the base body and between the first conductive layer and the base body. The second insulating layer is provided between the first insulating layer and the base body. A first thickness of the first insulating layer at a first position is smaller than a second thickness of the first insulating layer at a second position. At the first position, the first insulating layer overlaps the first conductive layer in a first direction from the second semiconductor layer toward the first semiconductor layer. At the second position, the first insulating layer does not overlap the first conductive layer in the first direction. A second absolute value of a difference between a third thickness of the second insulating layer at the first position and a fourth thickness of the second insulating layer at the second position is smaller than a first absolute value of a difference between the first thickness and the second thickness.

According to one embodiment, a semiconductor light emitting device includes a base body, first to third semiconductor layers, first and second insulating layers. The first semiconductor layer is spaced apart from the base body in a first direction. The first semiconductor layer includes a first semiconductor region and a second semiconductor region juxtaposed with the first semiconductor region in a direction intersecting the first direction. The first semiconductor layer also includes a region of a first conductivity type. The second semiconductor layer is provided between the second semiconductor region and the base body and has a second conductivity type. The third semiconductor layer is provided between the first semiconductor layer and the second semiconductor layer. The first insulating layer is provided between the first semiconductor region and the base body and between the second semiconductor layer and the base body. The second insulating layer is provided between the first insulating layer and the base body. A first thickness of the first insulating layer at a first position is smaller than a second thickness of the first insulating layer at a second position. At the first position, the first insulating layer overlaps the second semiconductor region in the first direction. At the second position, the first insulating layer overlaps the first semiconductor region in the first direction. A second absolute value of a difference between a third thickness of the second insulating layer at the first position and a fourth thickness of the second insulating layer at the second position is smaller than a first absolute value of a difference between the first thickness and the second thickness.

According to one embodiment, a semiconductor light emitting device includes a base body, a first layer, first and second insulating layers. The first layer is spaced apart from the base body in a first direction. The first layer includes a first region and a second region juxtaposed with the first region in a direction intersecting the first direction. A distance between the first region and the base body is shorter than a distance between the second region and the base body. The first insulating layer is provided between the first region and the base body and between the second region and the base body. The second insulating layer is provided between the first insulating layer and the base body. A first thickness of the first insulating layer at a first position is smaller than a second thickness of the first insulating layer at a second position. At the first position, the first insulating layer overlaps the first region in a first direction from the base body toward the first layer. At the second position, the first insulating layer overlaps the second region in the first direction. A second absolute value of a difference between a third thickness of the second insulating layer at the first position and a fourth thickness of the second insulating layer at the second position is smaller than a first absolute value of a difference between the first thickness and the second thickness.

Various embodiments will be described hereinafter with reference to the accompanying drawings.

Incidentally, the drawings are schematic or conceptual, and the relationship between the thickness and width of each portion, the proportions of sizes between portions, etc., are not necessarily the same as the actual ones. Further, the dimensions and the proportions may sometimes be illustrated differently between the drawings even in the case where the same portion is illustrated.

Incidentally, in the specification and the drawings, the same components as those previously described with respect to the foregoing drawing are denoted by the same reference numerals, and a detailed description is omitted as appropriate.

### First Embodiment

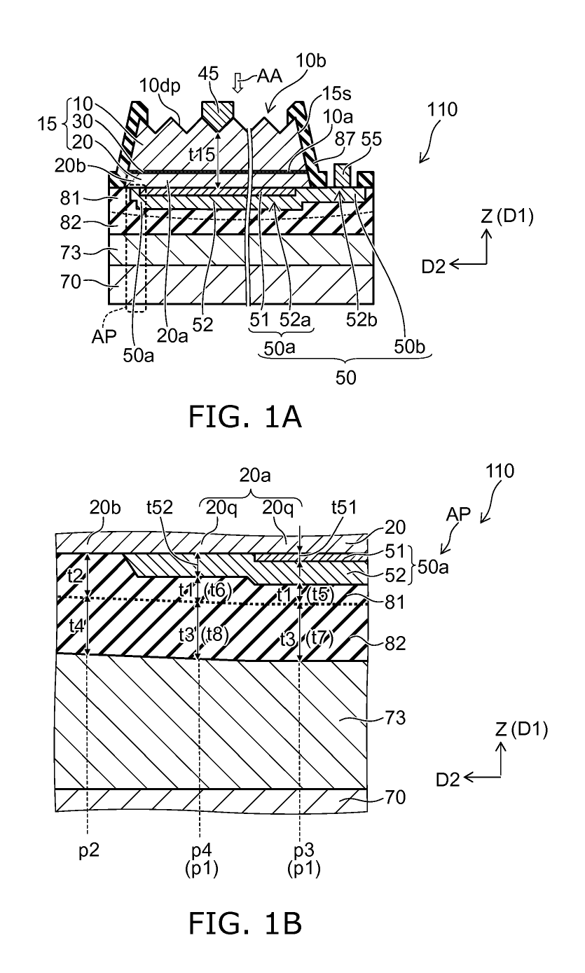

FIG. 1A and FIG. 1B are schematic cross-sectional views illustrating a semiconductor light emitting device according to a first embodiment.

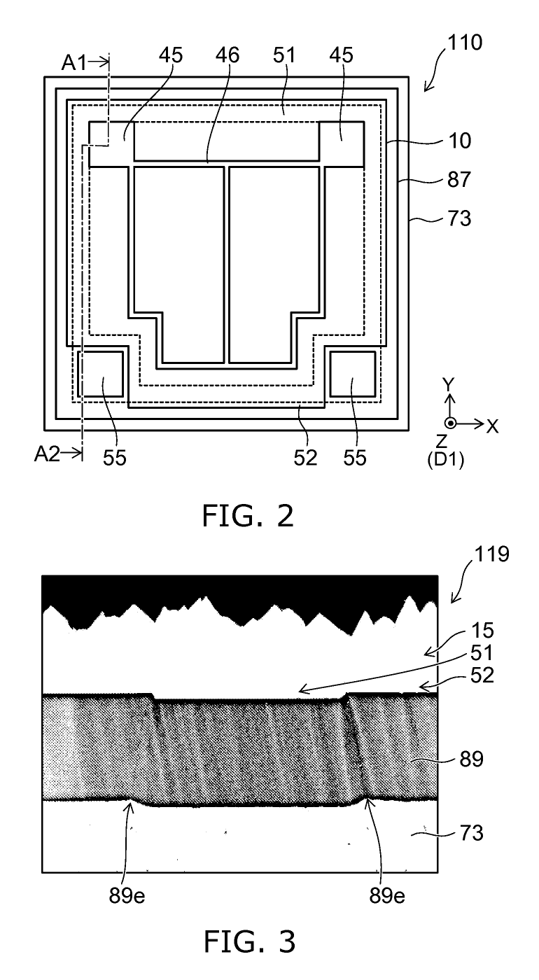

FIG. 2 is a schematic plan view illustrating the semiconductor light emitting device according to the first embodiment.

FIG. 1A is a cross-sectional view taken along the line A1-A2 of FIG. 2. FIG. 1B shows a portion AP of FIG. 1A on an enlarged scale. FIG. 2 is a plan view seen from the direction indicated by the arrow AA shown in FIG. 1A. In FIG. 2, some components are indicated by broken lines in a see-through view.

As shown in FIG. 1A, FIG. 1B, and FIG. 2, a semiconductor light emitting device 110 according to the embodiment includes a base body 70, a first semiconductor layer 10, a second semiconductor layer 20, a third semiconductor layer 30, a first conductive layer 50, a first insulating layer 81, and a second insulating layer 82.

As the base body 70, for example, a semiconductor substrate made of Si or the like is used. Examples of the base body 70 will be described later.

The first semiconductor layer 10 includes a first conductivity-type region.

The second semiconductor layer 20 is provided between the first semiconductor layer 10 and the base body 70. The second semiconductor layer 20 is of a second conductivity type.

For example, the first conductivity type is an n-type, and the second conductivity type is a p-type. It is also possible that the first conductivity type is a p-type, and the second conductivity type is an n-type. In the following example, the first conductivity type is an n-type, and the second conductivity type is a p-type.

The third semiconductor layer 30 is provided between the first semiconductor layer 10 and the second semiconductor layer 20. The third semiconductor layer 30 includes, for example, an active layer. The third semiconductor layer 30 is, for example, a light emitting unit. Examples of the third semiconductor layer 30 will be described later.

A direction directed from the second semiconductor layer 20 to the first semiconductor layer 10 is defined as Z-axis direction (first direction D1). The Z-axis direction is a direction in which the second semiconductor layer 20 and the first semiconductor layer 10 are stacked on each other. One direction perpendicular to the Z-axis direction is defined as X-axis direction. A direction perpendicular to the Z-axis direction and the X-axis direction is defined as Y-axis direction.

The first semiconductor layer 10, the second semiconductor layer 20, and the third semiconductor layer 30 are included in a stacked body 15. The stacked body 15 spreads along an X-Y plane.

The first semiconductor layer 10, the second semiconductor layer 20, and the third semiconductor layer 30 include, for example, a nitride semiconductor.

A first conductive layer 50 is provided between a part (first portion 20a) of the second semiconductor layer 20 and the base body 70.

That is, the second semiconductor layer 20 includes the first portion 20a and a second portion 20b. The second portion 20b is juxtaposed with the first portion 20a in a direction (for example, a second direction D2) intersecting the first direction D1. The first conductive layer 50 is not provided between the second portion 20b and the base body 70.

The first conductive layer 50 is electrically connected to the second semiconductor layer 20.

In the specification, the electrically connected state includes a state where a first conductor and a second conductor are in direct contact with each other. Further, the electrically connected state includes a state where a third conductor is inserted between the first conductor and the second conductor so that an electric current flows between the first conductor and the second conductor through the third conductor.

At least a part of the first conductive layer 50 makes an ohmic contact with the second semiconductor layer 20. The first conductive layer 50 has light reflectivity.

The first insulating layer 81 is provided between another part (second portion 20b) of the second semiconductor layer 20 and the base body 70 (first installation position) and between the first conductive layer 50 and the base body 70 (second installation position).

The second insulating layer 82 is provided between the first insulating layer 81 and the base body 70.

The first insulating layer 81 and the second insulating layer 82 include, for example, silicon oxide, silicon nitride, silicon oxynitride, or the like. Examples of materials of these insulating layers will be described later.

In this example, in the semiconductor light emitting device 110, a first pad 45 and a second pad 55 are provided.

Between the first pad 45 and the third semiconductor layer 30, the first semiconductor layer 10 is disposed. The first pad 45 is electrically connected to the first semiconductor layer 10. In the case where the first semiconductor layer 10 is an n-type semiconductor, the first pad 45 becomes an n-side pad.

As shown in FIG. 2, in this example, a linear electrode 46 is provided. The electrode 46 is electrically connected to the first pad 45. Between the electrode 46 and the third semiconductor layer 30, the first semiconductor layer 10 is disposed. The electrode 46 has, for example, a function to spread an electric current.

As shown in FIG. 1A, a part (first conductive portion 50a) of the first conductive layer 50 is disposed between the above-mentioned part (first portion 20a) of the second semiconductor layer 20 and the base body 70.

Another part (second conductive portion 50b) of the first conductive layer 50 is disposed between the second pad 55 and the base body 70.

That is, the first conductive portion 50a of the first conductive layer 50 overlaps with the second semiconductor layer 20 in the first direction D1. On the other hand, the second conductive portion 50b of the first conductive layer 50 does not overlap with the second semiconductor layer 20 in the first direction D1, but overlaps with the second pad 55 in the first direction D1.

The second pad 55 is electrically connected to the second conductive portion 50b of the first conductive layer 50.

In this example, the first conductive layer 50 has a configuration of a stacked film.

That is, the first conductive layer 50 includes a first metal layer 51 and a second metal layer 52. The first metal layer 51 is provided between a part 52a of the second metal layer 52 and the second semiconductor layer 20. The first metal layer 51 overlaps with a part 20p of the first portion 20a in the first direction D1. The first metal layer 51 does not overlap with another part 20q of the first portion 20a in the first direction D1. The second metal layer 52 overlaps with the part 20p and the part 20q in the first direction D1.

The above-mentioned part (first conductive portion 50a) of the first conductive layer 50 includes the first metal layer 51 and the above-mentioned part 52a of the second metal layer 52. The another part (second conductive portion 50b) of the first conductive layer 50 includes another part 52b of the second metal layer 52.

The first metal layer 51 makes an ohmic contact with the second semiconductor layer 20. The second metal layer 52 covers, for example, the first metal layer 51 to protect the first metal layer 51. The second metal layer 52 has a function to spread an electric current. On the above-mentioned another part 52b of the second metal layer 52, the second pad 55 is provided.

At least a part of the second pad 55 overlaps with at least a part of the stacked body 15 which includes the first semiconductor layer 10, the third semiconductor layer 30, and the second semiconductor layer 20 in a direction (for example, the second direction) intersecting the first direction D1 (the Z-axis direction directed from the second semiconductor layer 20 to the first semiconductor layer). For example, at least a part of the second pad 55 overlaps with at least a part of the semiconductor layer 20 in the second direction. At least a part of the second pad 55 may overlap with at least a part of the third semiconductor layer 30 in the second direction. At least a part of the second pad 55 may overlap with at least a part of the first semiconductor layer 10 in the second direction D2.

In this example, a third metal layer 73 is further provided.

The third metal layer 73 is provided between the base body 70 and the second insulating layer 82. The third metal layer 73 bonds, for example, the second insulating layer 82 and the base body 70. The third metal layer 73 is, for example, a bonding layer.

An electric voltage is applied between the first pad 45 and the second pad 55. From these pads, an electric current is supplied, and a light is emitted from the stacked body 15 (specifically, the third semiconductor layer 30).

The semiconductor light emitting device 110 is an LED. A light (luminous light) emitted from the third semiconductor layer 30 is reflected by the first conductive layer 50 and emitted to the outside of the semiconductor light emitting device 110. The surface of the first semiconductor layer 10 becomes a light emitting surface.

In the semiconductor light emitting device 110, the thickness of the first insulating layer 81 is made different in a level difference portion due to the first conductive layer 50. On the other hand, a difference in the thickness of the second insulating layer 82 is small.

As shown in FIG. 1B, the first insulating layer 81 has a thickness (first thickness t1) at a first position p1 where the first insulating layer 81 overlaps with the first conductive layer 50 in the first direction D1. The first insulating layer 81 has a thickness (second thickness t2) at a second position p2 where the first insulating layer 81 does not overlap with the first conductive layer 50 in the first direction D1. The first thickness t1 is smaller than the second thickness t2.

The second insulating layer 82 has a thickness (third thickness t3) at the first position p1. The second insulating layer 82 has a thickness (fourth thickness t4) at the second position p2. A difference between the third thickness t3 and the fourth thickness t4 is small.

That is, an absolute value (second absolute value) of the difference between the third thickness t3 and the fourth thickness t4 is smaller than an absolute value (first absolute value) of a difference between the first thickness t1 and the second thickness t2. The first thickness t1 to the fourth thickness t4 are, for example, lengths along the first direction D1. The first position p1 and the second position p2 are positions in the X-Y plane.

In this manner, a level difference due to the first conductive layer 50 is relaxed by the first insulating layer 81. A level difference in the surface of the first insulating layer 81 facing the second insulating layer 82 is smaller than the level difference due to the first conductive layer 50.

As described below, it was found that the film quality of the insulating layer is liable to be deteriorated in a level difference portion formed by an outer periphery of the first conductive layer 50 or the like. The inventor focused on this deterioration of the film quality and developed the configuration of the semiconductor light emitting device 110 described above.

In addition to this, in the semiconductor light emitting device 110, the thickness of the first insulating layer 81 is made different also in a level difference portion due to the first metal layer 51 of the first conductive layer 50.

That is, as shown in FIG. 1B, as the first conductive layer 50, the first metal layer 51 and the second metal layer 52 are provided.

The first insulating layer 81 has a thickness (fifth thickness t5) at a third position p3 where the first insulating layer 81 overlaps with the first metal layer 51 in the first direction D1. The first insulating layer 81 has a thickness (sixth thickness t6) at a fourth position p4 where the first insulating layer 81 overlaps with the first conductive layer 50 (in this case, the second metal layer 52) in the first direction D1 but does not overlap with the first metal layer 51 in the first direction D1. The fifth thickness t5 is smaller than the sixth thickness t6.

The second insulating layer 82 has a thickness (seventh thickness t7) at the third position p3. The second insulating layer 82 has a thickness (eighth thickness t8) at the fourth position p4. An absolute value (fourth absolute value) of a difference between the seventh thickness t7 and the eighth thickness t8 is smaller than an absolute value (third absolute value) of a difference between the fifth thickness t5 and the sixth thickness t6. The fifth thickness t5 to the eighth thickness t8 are, for example, lengths along the first direction D1. The third position p3 and the fourth position p4 are positions in the X-Y plane.

In this manner, a level difference due to the first metal layer 51 is relaxed by the first insulating layer 81. A level difference in the surface of the first insulating layer 81 facing the second insulating layer 82 is smaller than the level difference due to the first metal layer 51.

In the case where the first metal layer 51 and the second metal layer 52 are provided, as the above-mentioned first thickness t1, either of the fifth thickness t5 and the sixth thickness t6 may be used. As the above-mentioned first thickness t1, an average of the fifth thickness t5 and the sixth thickness t6 may be used.

In the case where the first metal layer 51 and the second metal layer 52 are provided, as the above-mentioned second thickness t2, either of the seventh thickness t7 and the eighth thickness t8 may be used. As the above-mentioned second thickness t2, an average of the seventh thickness t7 and the eighth thickness t8 may be used.

FIG. 3 is a microscope image illustrating a semiconductor light emitting device.

FIG. 3 is an SEM image of a cross section of a semiconductor light emitting device 119 of Reference Example. In the semiconductor light emitting device 119, in place of the above-mentioned first insulating layer 81 and second insulating layer 82, a single-layered insulating layer 89 is provided. It was found that such a semiconductor light emitting device 119 sometimes has a low breakdown voltage.

As shown in FIG. 3, when the insulating film 89 in the semiconductor light emitting device 119 is observed, in a level difference portion due to the first metal layer 51, a discontinuous portion 89e is observed in the insulating film 89. In such a discontinuous portion 89e, the insulation performance is considered to be locally low. This discontinuous portion 89e is considered to correspond to a portion where a film grown at a different position is joined in a level difference portion when the insulating film 89 is formed.

That is, when a dielectric film is formed on a surface with a level difference, for example, a dielectric body in a level difference portion grows in multiple growth directions, so that a portion where films having mutually different growth directions come in contact with one another is generated. In this contact portion, a poor quality boundary surface is generated. At this boundary surface, the quality is extremely poor. For example, an etching rate at this boundary surface is very high. A breakdown voltage at this boundary surface is low. In the semiconductor light emitting device 119, leakage is liable to occur in a region where the quality is poor in the level difference portion. Due to this, the breakdown voltage is liable to drop.

In the embodiment, by the first insulating layer 81, the level difference is made small, and the second insulating layer 82 is provided thereon. For example, since the level difference is made small by the first insulating layer 81, the generation of the above-mentioned discontinuous portion is suppressed in the second insulating layer 82.

For example, an etching rate at a position where the second insulating layer 82 overlaps with an outer periphery of the first conductive layer 50 in the first direction D1 is substantially the same as an etching rate at a position different from the position where the second insulating layer 82 overlaps with an outer periphery of the first conductive layer 50 in the first direction D1.

Hereinafter, an example of a method for manufacturing the first insulating layer 81 and the second insulating layer 82 will be described.

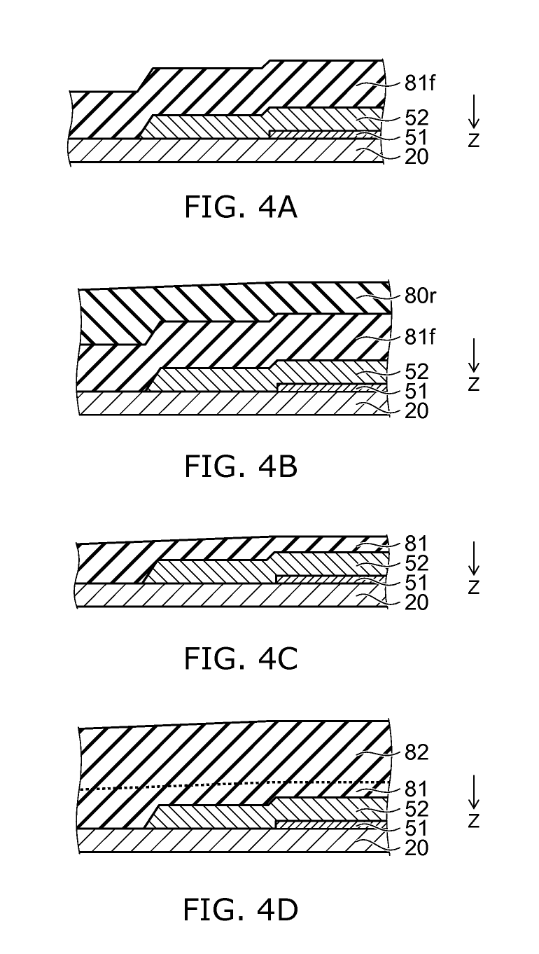

FIG. 4A to FIG. 4D are schematic cross-sectional views of a process order illustrating a part of a method for manufacturing the semiconductor light emitting device according to the first embodiment.

As shown in FIG. 4A, on a part of the second semiconductor layer 20, the first metal layer 51 is provided. The second metal layer 52 is provided so as to cover the first metal layer 51. On the second metal layer 52 and the semiconductor layer 20, a first insulating film 81f which becomes the first insulating layer 81 is formed.

As shown in FIG. 4B, on the first insulating film 81f, a sacrifice film 80r is formed. The sacrifice film 80r is, for example, a resist (for example, a photoresist). For example, by appropriately selecting the viscosity, thickness, and properties of the photoresist, a flat surface (for example, a smooth surface) is obtained on the surface of the photoresist. For example, the thickness of the sacrifice film 80r is different mutually in a region where the first metal layer 51 is not provided, a region where the second metal layer 52 is not provided, a region where the first metal layer 51 and the second metal layer 52 are provided.

As shown in FIG. 4C, an etching back treatment is performed. For example, wet etching or dry etching is performed. Conditions in which the etching rates for the photoresist and the first insulating film 81f are close to each other are used. Etching is performed until the photoresist is gone. By doing this, the flat surface of the photoresist is transcribed into the first insulating film 81f. That is, a time in which the sacrifice film 80r is removed and the first insulating film 81f is exposed is different depending on the above-mentioned regions. Due to this, the upper surface of the first insulating film 81f is flattened. In this manner, the first insulating layer 81 is formed.

As shown in FIG. 4D, the second insulating layer 82 is formed. Since the upper surface of the first insulating layer 81 is flat, the second insulating layer 82 is flat.

In the first insulating film 81f in a state illustrated in FIG. 4A, the above-mentioned discontinuous portion may be generated in a level difference portion due to the presence or absence of the first metal layer 51 or in a level difference portion due to the presence or absence of the second metal layer 52. However, thereafter, the first insulating film 81f is flattened, and therefore, the generation of such a discontinuous portion can be suppressed in the second insulating layer 82 formed thereon. According to this, in the semiconductor light emitting device 110 according to the embodiment, high insulation performance is obtained. Thus, a high breakdown voltage is obtained.

In the manufacturing method described above, the sacrifice film 80r described with respect to FIG. 4B may be omitted. At this time, in a state shown in FIG. 4A, for example, a CMP (Chemical Mechanical Polishing) treatment or the like is performed. An abrasive agent, an additive, the amount of the abrasive agent to be contained, the concentration of the additive, and the like are set as appropriate. By this CMP treatment, the surface of the first insulating film 81f can be flattened. In the case where the area ratio of protrusions is high, the treatment conditions and the treatment time are set as appropriate.

In the embodiment, an SOG (Spin on Glass) may be used as the first insulating film 81f. In this case, by spin coating, the first insulating film 81f is formed, and a flat surface is obtained. The viscosity of a material of the SOG, the thickness thereof, the heating temperature, the properties, and the like are set as appropriate. The effect of the first conductive layer 50 on the contact properties is suppressed. The desorption of an organic material gas is suppressed.

By these methods, the upper surface of the first insulating film 81f can be flattened. Thereafter, the second insulating layer 82 is formed.

In the semiconductor light emitting device 110, the second absolute value is smaller than the thickness t52 of the second metal layer 52. The second absolute value is, for example, ½ or less of the thickness t52 of the second metal layer 52. The second absolute value is preferably, for example, more than 0 times and ⅕ times or less of the thickness t52 of the second metal layer 52.

An absolute value of a difference between the first absolute value and the second absolute value is preferably ½ times or more and 1.2 times or less of the thickness t52 of the second metal layer 52. The first absolute value is preferably ½ times or more and 1.2 times or less of the thickness t52 of the second metal layer 52.

The second absolute value is smaller than the thickness t51 of the first metal layer 51. The second absolute value is, for example, ½ or less of the thickness t51 of the first metal layer 51. The second absolute value is preferably, for example, more than 0 times and ⅕ times or less of the thickness t51 of the first metal layer 51.

An absolute value of a difference between the first absolute value and the second absolute value is preferably ½ times or more and 1.2 times or less of the thickness t51 of the first metal layer 51. The first absolute value is preferably ½ times or more and 1.2 times or less of the thickness t51 of the first metal layer 51.

The second absolute value is smaller than the thickness of the first conductive layer 50 (in this case, the sum of the thickness t51 of the first metal layer 51 and the thickness t52 of the second metal layer 52). The second absolute value is, for example, ½ or less of the thickness of the first conductive layer 50. The second absolute value is preferably, for example, more than 0 times and ⅕ times or less of the thickness of the first conductive layer 50.

An absolute value of a difference between the first absolute value and the second absolute value is preferably ½ times or more and 1.2 times or less of the thickness of the first conductive layer 50. The first absolute value is preferably ½ times or more and 1.2 times or less of the thickness of the first conductive layer 50.

The fourth absolute value is smaller than the thickness t51 of the first metal layer 51. The fourth absolute value is, for example, ½ or less of the thickness t51 of the first metal layer 51. The fourth absolute value is preferably, for example, more than 0 times and ⅕ times or less of the thickness t51 of the first metal layer 51.

An absolute value of a difference between the third absolute value and the fourth absolute value is preferably ½ times or more and 1.2 times or less of the thickness t51 of the first metal layer 51. The third absolute value is preferably ½ times or more and 1.2 times or less of the thickness t51 of the first metal layer 51.

For example, the semiconductor light emitting device 110 is a thin-film type LED. As described later, in the semiconductor light emitting device 110, after the crystal of the stacked body 15 is grown on a substrate for growth, the stacked body 15 is bonded to the base body 70. Then, the substrate for growth is removed. The substrate for growth is thick and has a large heat capacity. In the semiconductor light emitting device 110, the substrate for growth is removed, and therefore, the heat capacity of the semiconductor light emitting device 110 can be made small, and the heat dissipation performance can be enhanced.

In the example shown in FIG. 1A, unevenness 10dp are provided on the light emitting surface of the first semiconductor layer 10. That is, the first semiconductor layer 10 has a first surface 10a and a second surface 10b. The first surface 10a is a surface on the side of the third semiconductor layer 30. The first surface 10a faces the third semiconductor layer 30. The second surface 10b is a surface on the opposite side to the first surface 10a. The second surface 10b becomes a light emitting surface. On the second surface 10b, the unevenness 10dp are provided. By providing the unevenness 10dp, a light can be efficiently extracted from the stacked body 15.

The heights (depths) of the unevenness 10dp are, for example, 0.5 times or more and 30 times or less of a peak wavelength. The heights (depths) of the unevenness are, for example, 0.2 micrometers (μm) or more and 2 μm or less. The width of a protrusion of the unevenness in a direction (which may be, for example, the second direction D2) perpendicular to the first direction D1 is, for example, 0.5 times or more and 30 times or less of a peak wavelength. The intensity of a light emitted from the third semiconductor layer 30 substantially reaches the peak (maximum) in the peak wavelength.

In the semiconductor light emitting device 110, since the substrate for growth is removed, a distance between the upper surface (the light emitting surface, that is, the second surface 10b) of the first semiconductor layer 10 and the first conductive layer 50 is short.

For example, a distance t15 between the first conductive layer 50 and the second surface 10b of the first semiconductor layer 10 is 1.5 μm or more and 30 μm or less. According to the configuration in which the substrate for growth is removed, the distance t15 can be made short in this manner.

For example, the distance t15 is the shortest distance between the first conductive layer 50 and the second surface 10b. In the case where the unevenness 10dp are provided, the distance t15 corresponds to a distance between a bottom portion of the unevenness 10dp and the first conductive layer 50. In this example, the distance t15 corresponds to a distance between the first pad 45 and the first conductive layer 50 (shortest distance).

In the semiconductor light emitting device 110, an insulating film 87 is further provided. The insulating film 87 is provided on a side surface 15s of the stacked body 15. The insulating film 87 covers the side surface 15s of the stacked body 15. The side surface 15s of the stacked body 15 is a surface intersecting the X-Y plane. By the insulating film 87, an electric current flowing through the side surface 15s of the stacked body 15 can be suppressed, so that the breakdown voltage can be improved. Then, high reliability is obtained. The insulating film 87 includes, for example, silicon oxide. The insulating film 87 is formed by, for example, plasma CVD (Chemical Vapor Deposition) or the like.

The base body 70 is, for example, electrically conductive. The base body 70 may include a semiconductor such as Si. The base body 70 may include a metal. The base body 70 may be electrically insulating.

The first metal layer 51 includes, for example, at least either of silver and rhodium. The first metal layer 51 may include a silver alloy. As the first metal layer 51, for example, a silver layer, a rhodium layer, or a silver alloy layer is used. According to this, a high light reflectance is obtained. Between the first metal layer 51 and the second semiconductor layer 20, a low contact resistance is obtained. The first metal layer 51 may include aluminum.

The thickness t51 of the first metal layer 51 is, for example, 10 nm or more and 1,000 nm or less.

The second metal layer 52 includes, for example, at least any of Ni, Pt, Au, and Ti. The second metal layer 52 includes, for example, a Ni-containing region, a Pt-containing region, an Au-containing region, and a Ti-containing region. Between the Ti-containing region and the first metal layer 51, the Au-containing region is provided. Between the Au-containing region and the first metal layer 51, the Pt-containing region is provided. Between the Pt-containing region and the first metal layer 51, the Ni-containing region is provided.

The second metal layer 52 has, for example, reflectivity. The second metal layer 52 may include at least one of silver and aluminum.

The thickness t52 of the second metal layer 52 is, for example, 100 nm or more and 10,000 nm or less.

At least one of the first insulating layer 81 and the second insulating layer 82 includes an oxide including at least one element selected from the group consisting of silicon, aluminum, zirconium, hafnium, and titanium. At least one of the first insulating layer 81 and the second insulating layer 82 may include, for example, a nitride including at least one element selected from the above-mentioned group. At least one of the first insulating layer 81 and the second insulating layer 82 may include an oxynitride including at least one element selected from the above-mentioned group.

In the case where these insulating layers (at least one of the first insulating layer 81 and the second insulating layer 82) include silicon oxide, light absorption is low. Then, high reliability is obtained. In the case where these insulating layers include silicon nitride, high heat conductivity is obtained. Then, low thermal resistance is obtained.

In the case where the first insulating layer 81 and the second insulating layer 82 include silicon oxide, the total thickness of these layers is preferably, for example, 3 μm or less. If the total thickness exceeds this value, heat dissipation performance is decreased. In the case where the first insulating layer 81 and the second insulating layer 82 include silicon nitride, the total thickness of these layers is preferably 20 μm or less. If the total thickness exceeds this value, heat dissipation performance is decreased.

In the embodiment, in the case where the first insulating layer 81 and the second insulating layer 82 include silicon oxide and the total thickness of these layers is 3 μm, a DC breakdown voltage exceeding 3,000 V is obtained.

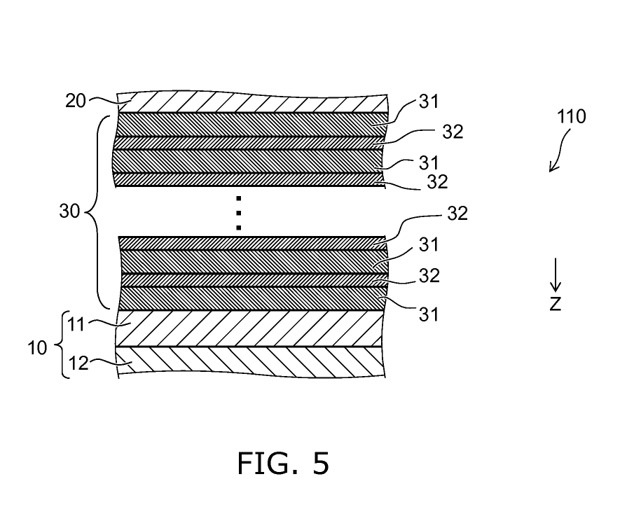

FIG. 5 is a schematic cross-sectional view illustrating a part of the semiconductor light emitting device according to the first embodiment. FIG. 5 illustrates the stacked body 15.

As shown in FIG. 5, the third semiconductor layer 30 includes multiple barrier layers 31 and well layers 32, each provided between the respective multiple barrier layers 31. For example, the multiple barrier layers 31 and the multiple well layers 32 are alternately arranged along the Z-axis direction.

The well layer 32 includes, for example, Alₓ₁Ga₁₋ₓ₁₋ₓ₂Inₓ₂N (0≦x≦1, 0≦x2≦1, x1≦x2≦1). The barrier layer 31 includes Al_{y1}Ga_{1-y1-y2}In_{y2}N (0≦y1≦1, 0≦y2≦1, y1+y2≦1). The band gap energy of the barrier layer 31 is larger than the band gap energy of the well layer 32.

For example, the third semiconductor layer 30 has a single quantum well (SQW) structure. At this time, the third semiconductor layer 30 includes two barrier layers 31 and the well layer 32 provided between the barrier layers 31.

For example, the third semiconductor layer 30 may have a multi quantum well (MQW) structure. At this time, the third semiconductor layer 30 includes three or more barrier layers 31 and the well layers 32, each provided between the respective barrier layers 31.

The peak wavelength of a light (luminous light) emitted from the third semiconductor layer 30 is, for example, 210 nanometers (nm) or more and 780 nm or less. In the embodiment, the peak wavelength is arbitrary.

In this example, the first semiconductor layer 10 includes a first conductivity-type region 11 (for example, an n-type semiconductor layer) and a low-impurity concentration region 12. Between the third semiconductor layer 30 and the low-impurity concentration region 12, the first conductivity-type region 11 is provided. The impurity concentration in the low-impurity concentration region 12 is lower than the impurity concentration in the first conductivity-type region 11. The impurity concentration in the low-impurity concentration region 12 is, for example, 1×10¹⁷ cm⁻³ or less.

As the first conductivity-type region 11 of the first semiconductor layer 10, for example, a GaN layer containing an n-type impurity is used. As the n-type impurity, at least any of Si, O, Ge, Te, and Sn is used. The first conductivity-type region 11 includes, for example, an n-side contact layer.

As the low-impurity concentration region 12, for example, a non-doped GaN layer is used. The low-impurity concentration region 12 may include an Al-including nitride semiconductor (AlGaN or AlN). Such a GaN layer, an AlGaN layer, or an AlN layer may include, for example, a buffer layer used in the growth of the crystal of the semiconductor layer or the like.

As the second semiconductor layer 20, for example, a GaN layer containing a p-type impurity is used. As the p-type impurity, at least any of Mg, Zn, and C is used. The second semiconductor layer 20 includes, for example, a p-side contact layer.

The thickness of the first conductivity-type region 11 is, for example, 100 nm or more and 10,000 nm or less. The thickness of the low-impurity concentration region 12 is, for example, 1 nm or more and 10,000 nm or less.

The thickness of the first semiconductor layer 10 is, for example, 100 nm or more and 20,000 nm or less.

The thickness of the second semiconductor layer 20 is, for example, 10 nm or more and 5,000 nm or less.

The thickness of the third semiconductor layer 30 is, for example, 0.3 nm or more and 1,000 nm or less.

The thickness of the barrier layer 31 is, for example, 0.1 nm or more and 500 nm or less.

The thickness of the well layer 32 is, for example, 0.1 nm or more and 100 nm or less.

Hereinafter, an example of the method for manufacturing the semiconductor light emitting device 110 will be described.

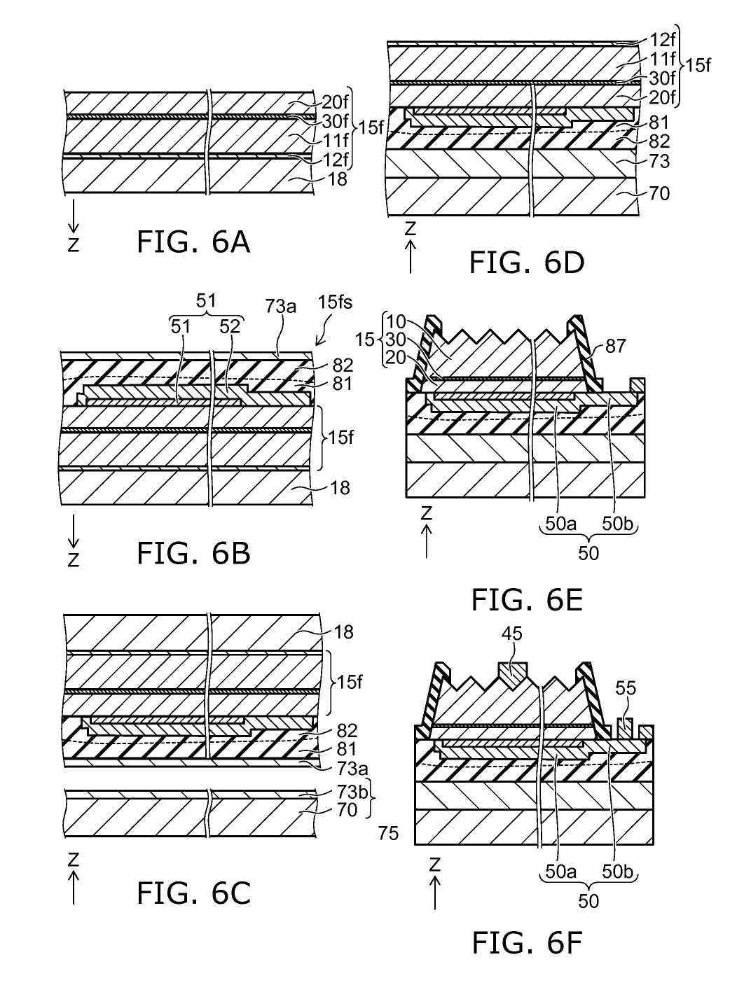

FIG. 6A to FIG. 6F are schematic cross-sectional views of a process order illustrating a method for manufacturing the semiconductor light emitting device according to the first embodiment.

As shown in FIG. 6A, on a substrate 18 (substrate for growth), a low-impurity concentration film 12f is formed. The low-impurity concentration film 12f includes, for example, a buffer film (for example, a stacked film of an Al-including nitride semiconductor film, or the like). The low-impurity concentration film 12f may further include a non-doped nitride semiconductor film (such as a non-doped GaN layer). On the low-impurity concentration film 12f, a first semiconductor film 11f is formed. The first semiconductor film 11f becomes at least a part of the first semiconductor layer 10. At least a part of the low-impurity concentration film 12f may become at least a part of the first semiconductor layer 10. On the first semiconductor film 11f, a third semiconductor film 30f which becomes the third semiconductor layer 30 is formed. On the third semiconductor film 30f, a second semiconductor film 20f which becomes the second semiconductor layer 20 is formed. By doing this, a stacked film 15f is obtained.

In the formation of these films, for example, epitaxial crystal growth is performed. For example, a metal-organic chemical vapor deposition (MOCVD) method, a metal organic vapor phase epitaxy (MOVPE) method, a molecular beam epitaxy (MBE) method, a halide vapor phase epitaxy (HVPE) method, or the like is used.

As the substrate 18, for example, a substrate of any of Si, SiO₂, AlO₂, quartz, sapphire, GaN, SiC, and GaAs is used. As the substrate 18, a substrate obtained by combining these materials may be used. The plane orientation of the substrate 18 is arbitrary.

As shown in FIG. 6B, on the second semiconductor film 20f, the first metal layer 51 having a predetermined shape is formed. The first metal layer 51 is, for example, a silver film. The thickness of this silver film is, for example, about 200 nm (for example, 150 nm or more and 250 nm or less). After forming the silver film, for example, a heat treatment (sintering treatment) is performed in an oxygen-containing atmosphere. The ratio of oxygen in the atmosphere is, for example, 0.1% or more and 100% or less. The ratio of an inert gas (for example, nitrogen or the like) in the oxygen-containing atmosphere is 0% or more and 99.9% or less. The temperature of the heat treatment is, for example, about 400° C. (for example, 350° C. or higher and 450° C. or lower).

On the first metal layer 51 (silver film) and on the second semiconductor film 20f, the second metal layer 52 is formed. As the second metal layer 52, for example, a Ni/Pt/Au/Ti stacked film is formed. The thickness of this stacked film is, for example, 1 μm.

In the formation of the first metal layer 51 and the second metal layer 52, for example, an E-gun vapor deposition method, a sputtering method, or the like is used. In the processing of these metal layers, for example, a lift-off method, wet etching, or the like is used.

The first insulating layer 81 and the second insulating layer 82 are formed thereon. In the formation of these insulating layers, for example, the process described with respect to FIG. 4A to FIG. 4B is used.

When silicon oxide is used as these insulating layers (dielectric layers), a leakage current can be particularly decreased. Thus, a higher breakdown voltage is obtained. When silicon nitride is used as these insulating layers, particularly high heat dissipation performance is obtained. The total thickness of these insulating layers is, for example, 0.1 μm or more and 20 μm or less. The thickness of the first insulating layer 81 is, for example, 0.05 μm or more and 10 μm or less. The thickness of the second insulating layer 82 is, for example, 0.05 μm or more and 10 μm or less. When the insulating layer is thin, high heat dissipation performance is obtained. When the insulating layer is thick, a high breakdown voltage is obtained. A film having high heat dissipation performance and a film having a high breakdown voltage may be stacked. In the formation of these insulating layers, for example, a sputtering method, an E-gun vapor deposition method, a CVD method, or a method using an SOG is used.

Further, a metal film 73a which becomes a part of the third metal layer 73 is formed. As a result, a structure body 15fs is formed.

For example, as the metal film 73a, a first Pt film, a first Ti film, a second Pt film, a second Ti film, and a first AuSn film are formed in this order. These films are formed by, for example, sputtering. Between the first AuSn film and the second insulating layer 82, the second Ti film is provided. Between the second Ti film and the second insulating layer 82, the second Pt film is provided. Between the second Pt film and the second insulating layer 82, the first Ti film is provided. Between the first Ti film and the second insulating layer 82, the first Pt film is provided. The thickness of the metal film 73a is, for example, about 2 μm (for example, 1.5 μm or more and 2.5 μm or less).

As shown in FIG. 6C, a counter substrate 75 is provided. The counter substrate 75 includes the base body 70 and a metal film 73b provided on the upper surface of the base body 70. The metal film 73b includes a third Ti film, a third Pt film, a fourth Ti film, and a second AuSn film. Between the second AuSn film and the base body 70, the fourth Ti film is provided. Between the fourth Ti film and the base body 70, the third Pt film is provided. Between the third Pt film and the base body 70, the third Ti film is provided. The thickness of the metal film 73b is, for example, about 2 μm (for example, 1.5 μm or more and 2.5 μm or less). The thickness of the base body 70 is, for example, about 700 μm (for example, 500 μm or more and 1,000 μm or less).

The structure body 15fs and the counter substrate 75 are disposed by bringing the metal film 73b and the metal film 73a into contact with each other. The resulting material is heated in this state to effect bonding by melting the metal film 73b and the metal film 73a. The heating temperature is, for example, 220° C. or higher and 300° C. or lower (for example, about 280° C.). The heating time is, for example, 3 minutes or more and 10 minute or less (for example, about 5 minutes).

As shown in FIG. 6D, the substrate 18 is removed. For example, in the case where the substrate 18 is a silicon substrate, grinding, dry etching (for example, RIE (Reactive Ion Etching)), or the like is used in the removal. For example, in the case where the substrate 18 is a sapphire substrate, LLO (Laser Lift Off), or the like is used in the removal. In this example, at least a part of the low-impurity concentration film 12f is left. The surface of the low-impurity concentration film 12f is exposed. In the embodiment, the low-impurity concentration film 12f may be removed. In this case, the surface of the first semiconductor film 11f is exposed.

As shown in FIG. 6E, on the surface of the low-impurity concentration film 12f or the surface of the first semiconductor film 11f, the unevenness 10dp are formed. For examples, the unevenness 10dp are formed by a wet treatment using an acid.

A part of the stacked film 15f is removed. In the removal, for example, RIE, wet etching, or the like is used. From the stacked film 15f, the stacked body 15 is obtained. That is, the first semiconductor layer 10, the second semiconductor layer 20, and the third semiconductor layer 30 are formed. The second conductive portion 50b (corresponding to a part of the second metal layer 52) of the first conductive layer 50 is exposed.

Thereafter, for example, a silicon oxide film which becomes the insulating film 87 is formed by, for example, CVD (Chemical Vapor Deposition). The thickness of the silicon oxide film is, for example, about 100 nm (for example, 50 nm or more and 200 nm or less).

As shown in FIG. 6F, a part of the silicon oxide film is removed, and in a region exposed by the removal, the first pad 45 and the second pad 55 are formed. For example, on the first semiconductor layer 10, the first pad 45 is formed. On the second conductive portion 50b of the first conductive layer 50, the second pad 55 is formed.

A wafer is diced into a predetermined shape. By doing this, the semiconductor light emitting device 110 is obtained.

In the above-mentioned manufacturing process, the order of the treatments may be changed within a technically feasible range. An annealing treatment may be performed as appropriate.

For example, by forming a stacked body which becomes multiple semiconductor light emitting devices on one wafer, and dicing the wafer, multiple semiconductor light emitting devices are obtained. A passivation (the insulating film 87) on a dicing street for dicing may be removed. By doing this, passivation cracking can be suppressed, so that the yield is improved.

According to need, a treatment of reducing the thickness of the base body 70 (for example, a silicon substrate) may be performed. For example, the thickness of the base body 70 is decreased to, for example, about approximately 150 μm (for example, 100 μm or more and 200 μm or less) by a treatment such as grinding. Thus, the heat capacity can be further reduced.

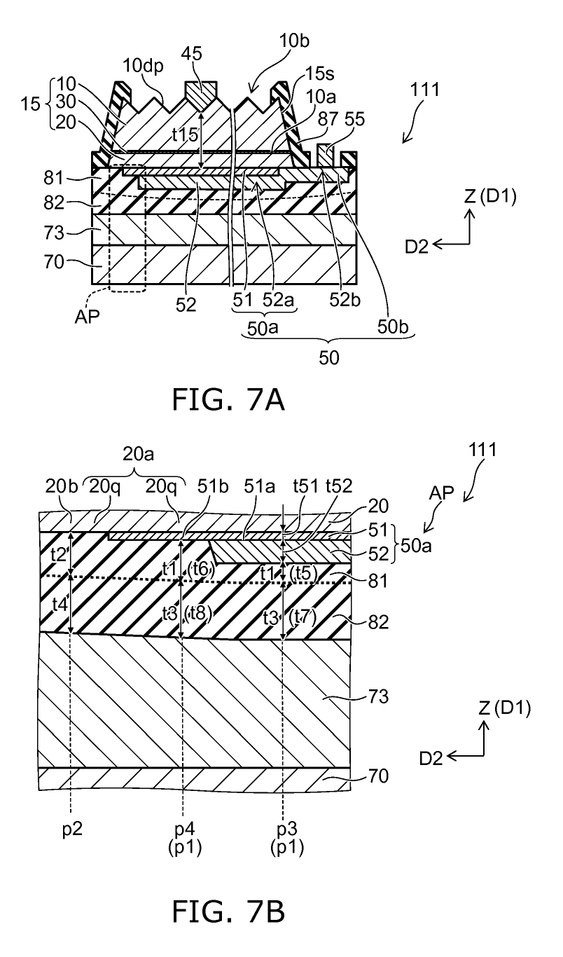

FIG. 7A and FIG. 7B are schematic cross-sectional views illustrating another semiconductor light emitting device according to the first embodiment.

FIG. 7B shows a portion AP of FIG. 7A on an enlarged scale.

As shown in FIG. 7A and FIG. 7B, also a semiconductor light emitting device 111 according to the embodiment includes a base body 70, a first semiconductor layer 10, a second semiconductor layer 20, a third semiconductor layer 30, a first conductive layer 50, a first insulating layer 81, and a second insulating layer 82. These configurations are the same as those of the semiconductor light emitting device 110, and therefore, a description thereof is omitted.

In the semiconductor light emitting device 111, the pattern of the first metal layer 51 and the second metal layer 52 included in the first conductive layer 50 is different from that of the semiconductor light emitting device 110.

A part 51a of the first metal layer 51 is provided between the second metal layer 52 and the second semiconductor layer 20. Another part 51b of the first metal layer 51 does not overlap with the second metal layer 52 in the first direction D1.

As shown in FIG. 7B, the first insulating layer 81 has a thickness (fifth thickness t5) at a third position p3 where the first insulating layer 81 overlaps with the part 51a of the first metal layer 51 in the first direction D1. The first insulating layer 81 has a thickness (sixth thickness t6) at a fourth position p4 where the first insulating layer 81 overlaps with the first metal layer 51 in the first direction D1 but does not overlap with the second metal layer 52 in the first direction D1. The sixth thickness t6 is a thickness of the first insulating layer 81 at a position where the first insulating layer 81 overlaps with the another part 51b of the first metal layer 51 in the first direction D1. The fifth thickness t5 is smaller than the sixth thickness t6.

The second insulating layer 82 has a thickness (seventh thickness t7) at the third position p3. The second insulating layer 82 has a thickness (eighth thickness t8) at the fourth position p4. The eighth thickness t8 is a thickness of the second insulating layer 82 at a position where the second insulating layer 82 overlaps with the another part 51b of the first metal layer 51 in the first direction D1.

An absolute value (fourth absolute value) of a difference between the seventh thickness t7 and the eighth thickness t8 is smaller than an absolute value (third absolute value) of a difference between the fifth thickness t5 and the sixth thickness t6. The fifth thickness t5 to the eighth thickness t8 are, for example, lengths along the first direction D1. The third position p3 and the fourth position p4 are positions in the X-Y plane.

In the semiconductor light emitting device 111, in the same manner as the semiconductor light emitting device 110, an absolute value (second absolute value) of a difference between the third thickness t3 and the fourth thickness t4 is smaller than an absolute value (first absolute value) of a difference between the first thickness t1 and the second thickness t2.

Also in the semiconductor light emitting device 111, a level difference due to the metal layer is flattened by the first insulating layer 81. Also in the semiconductor light emitting device 111, high insulation performance is obtained. Thus, a high breakdown voltage is obtained.

In the semiconductor light emitting device 111, the second absolute value is smaller than the thickness t52 of the second metal layer 52. The second absolute value is, for example, ½ or less of the thickness t52 of the second metal layer 52. The second absolute value is preferably, for example, more than 0 times and ⅕ times or less of the thickness t52 of the second metal layer 52.

An absolute value of a difference between the first absolute value and the second absolute value is preferably ½ times or more and 1.2 times or less of the thickness t52 of the second metal layer 52. The first absolute value is preferably ½ times or more and 1.2 times or less of the thickness t52 of the second metal layer 52.

The fourth absolute value is smaller than the thickness t52 of the second metal layer 52. The fourth absolute value is, for example, ½ or less of the thickness t52 of the second metal layer 52. The fourth absolute value is preferably more than 0 times and ⅕ times or less of the thickness t52 of the second metal layer 52.

An absolute value of a difference between the third absolute value and the fourth absolute value is preferably ½ times or more and 1.2 times or less of the thickness t52 of the second metal layer 52. The third absolute value is preferably ½ times or more and 1.2 times or less of the thickness t52 of the second metal layer 52.

### Second Embodiment

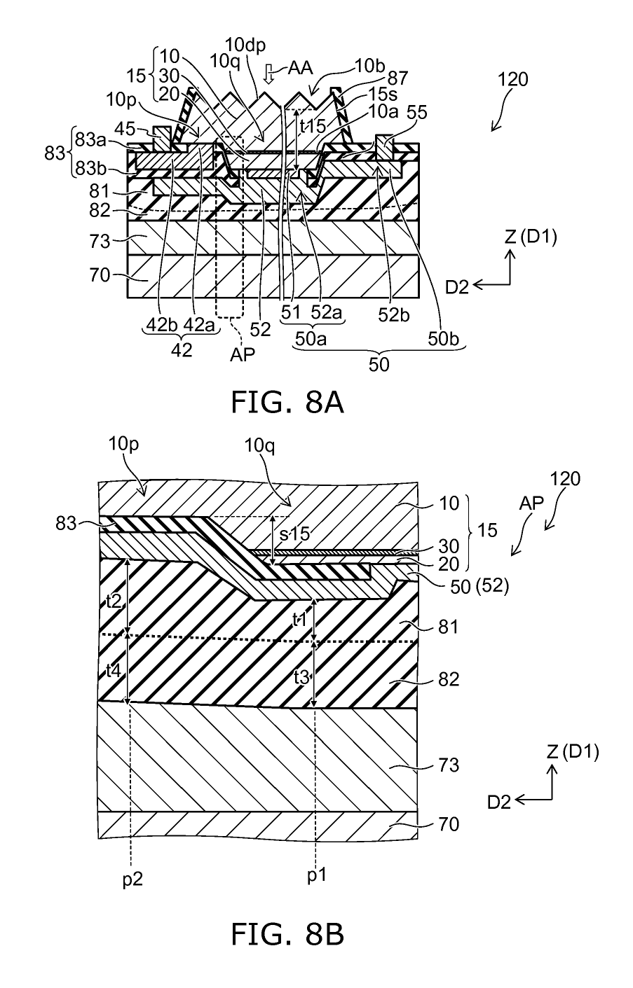

FIG. 8A and FIG. 8B are schematic cross-sectional views illustrating a semiconductor light emitting device according to a second embodiment.

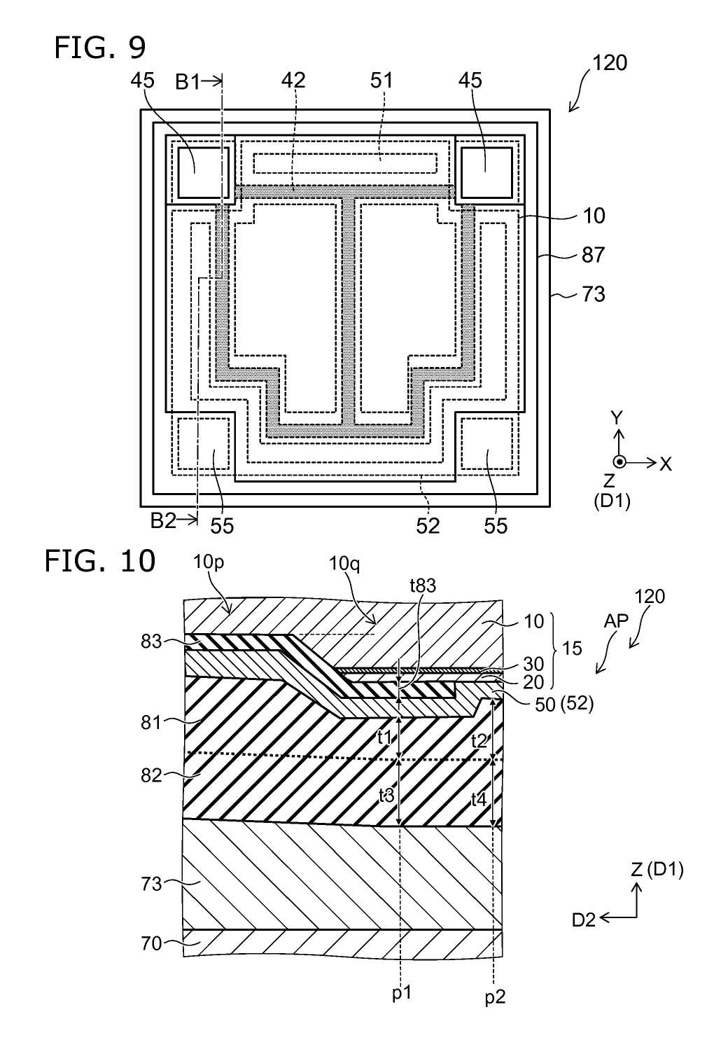

FIG. 9 is a schematic plan view illustrating the semiconductor light emitting device according to the second embodiment.

FIG. 8A is a cross-sectional view taken along the line B1-B2 of FIG. 9. FIG. 8B shows a portion AP of FIG. 8A on an enlarged scale. FIG. 9 is a plan view seen from the direction indicated by the arrow AA shown in FIG. 8A. In FIG. 9, some components are indicated by broken lines in a see-through view.

As shown in FIG. 8A, FIG. 8B, and FIG. 9, a semiconductor light emitting device 120 according to the embodiment includes a base body 70, a first semiconductor layer 10, a second semiconductor layer 20, a third semiconductor layer 30, a first conductive layer 50, a first insulating layer 81, and a second insulating layer 82.

The first semiconductor layer 10 is spaced apart from the base body 70 in a first direction D1. The first semiconductor layer 10 includes a first semiconductor region 10p and a second semiconductor region 10q. The second semiconductor region 10q is juxtaposed with the first semiconductor region 10p in a direction (for example, a second direction D2) intersecting the first direction D1. The first semiconductor layer 10 includes a first conductivity-type region 11 (see FIG. 5).

The second semiconductor layer 20 is provided between the second semiconductor region 10q and the base body 70. The second semiconductor layer 20 is of a second conductivity type.

The third semiconductor layer 30 is provided between the first semiconductor layer 10 and the second semiconductor layer 20.

The first semiconductor layer 10, the second semiconductor layer 20, and the third semiconductor layer 30 are included in a stacked body 15. To the first semiconductor layer 10, the second semiconductor layer 20, and the third semiconductor layer 30, the configurations (materials, thicknesses, etc.) described with respect to the semiconductor light emitting device 110 can be applied.

The first insulating layer 81 is provided between the first semiconductor region 10p and the base body 70 and between the second semiconductor layer 20 and the base body 70. The second insulating layer 82 is provided between the first insulating layer 81 and the base body 70.

In this example, between the second insulating layer 82 and the base body 70, a third metal layer 73 (for example, a bonding layer) is provided.

For example, the thickness of the second semiconductor region 10q is larger than the thickness of the first semiconductor region 10p. Further, between the second semiconductor region 10q and the base body 70, the second semiconductor layer 20 and the third semiconductor layer 30 are provided. Due to such a difference in thickness and also due to the second semiconductor layer 20 and the third semiconductor layer 30, a level difference is formed. In the embodiment, such a level difference is relaxed by the first insulating layer 81.

As shown in FIG. 8B, the first insulating layer 81 has a thickness (first thickness t1) at a first position p1 where the first insulating layer 81 overlaps with the second semiconductor region 10q in the first direction D1. The first insulating layer 81 has a thickness (second thickness t2) at a second position p2 where the first insulating layer 81 overlaps with the first semiconductor region 10p in the first direction D1. The first thickness t1 is smaller than the second thickness t2.

The second insulating layer 82 has a thickness (third thickness t3) at the first position p1. The second insulating layer 82 has a thickness (fourth thickness t4) at the second position p2. An absolute value (second absolute value) of a difference between the third thickness t3 and the fourth thickness t4 is smaller than an absolute value (first absolute value) of a difference between the first thickness t1 and the second thickness t2.

The level difference is relaxed by the first insulating layer 81, and therefore, in the second insulating layer 82, the generation of the above-mentioned discontinuous portion is suppressed. Due to this, in the embodiment, high insulation performance is obtained. Thus, a high breakdown voltage is obtained.

In the semiconductor light emitting device 120, the second absolute value is smaller than a level difference s15 in the stacked body 15. The second absolute value is ½ or less of the level difference s15 in the stacked body 15. The second absolute value is preferably more than 0 times and ⅕ times or less of the level difference s15 in the stacked body 15.

The level difference s15 is, for example, an absolute value of a difference between a distance between the first semiconductor region 10p and the base body 70 and a distance between the second semiconductor layer 20 and the base body 70. The level difference s15 corresponds to, for example, the sum of the level difference in the first semiconductor layer 10 (an absolute value of a difference between the thickness of the second semiconductor region 10q and the thickness of the first semiconductor region 10p), the thickness of the third semiconductor layer 30, and the thickness of the second semiconductor layer 20.

An absolute value of a difference between the first absolute value and the second absolute value is preferably ½ times or more and 1.2 times or less of the level difference s15 in the stacked body. The first absolute value is preferably ½ times or more and 1.2 times or less of the level difference s15 in the stacked body.

The semiconductor light emitting device 120 further includes a first pad 45, a second pad 55, a first conductive layer 50, and a second conductive layer 42.

A part (third conductive portion 42a) of the second conductive layer 42 is disposed between the base body 70 and the first semiconductor region 10p. The part (third conductive portion 42a) of the second conductive layer 42 is electrically connected to the first semiconductor region 10p.

Between the first pad 45 and the base body 70, another part (fourth conductive portion 42b) of the second conductive layer 42 is disposed. The first pad 45 is electrically connected to the another part (fourth conductive portion 42b) of the second conductive layer 42. As the second conductive layer 42, for example, an Al/Ti stacked film (having a thickness of, for example, about 1 μm) is used.

A part (first conductive portion 50a) of the first conductive layer 50 is disposed between the second semiconductor layer 20 and the base body 70. Another part (second conductive portion 50b) of the first conductive layer 50 is disposed between the second pad 55 and the base body 70. The second pad 55 is electrically connected to the another part (second conductive portion 50b) of the first conductive layer 50.

In this example, the first conductive layer 50 includes a first metal layer 51 and a second metal layer 52. The first metal layer 51 is provided between a part 52a of the second metal layer 52 and the second semiconductor layer 20. The first conductive portion 50a of the first conductive layer 50 includes the first metal layer 51 and the part 52a of the second metal layer 52. The second conductive portion 50b of the first conductive layer 50 includes another part 52b of the second metal layer 52.

In the semiconductor light emitting device 120, a part of the second metal layer 52 overlaps with the second conductive layer 42 in the first direction D1. Between the second metal layer 52 and the second conductive layer 42, an insulating film 83b is provided. Between a side surface of the third semiconductor layer 30 and the insulating film 83b and between a side surface of the second semiconductor layer 20 and the insulating film 83b, an insulating film 83a is provided. The insulating film 83a and the insulating film 83b are included in a third insulating layer 83.

An insulating film 87 is further provided. The insulating film 87 is provided on a side surface 15s of the stacked body 15. The insulating film 87 covers the side surface 15s of the stacked body 15.

The first semiconductor layer 10 has a first surface 10a on the side of the third semiconductor layer 30 and a second surface 10b. The second surface 10b is a surface on the opposite side to the first surface. On the second surface 10b, unevenness 10dp are provided.

A distance between the first conductive layer 50 and the second surface 10b is 1.5 μm or more and 30 μm or less. That is, the semiconductor light emitting device 120 is a thin-film type LED.

At least a part of the first pad overlaps with at least a part of the stacked body 15 which includes the first semiconductor layer 10, the third semiconductor layer 30, and the second semiconductor layer 20 in a direction (for example, the second direction D2) intersecting the first direction D1.

At least a part of the second pad 55 overlaps with at least a part of the stacked body 15 in a direction (for example, the second direction D2) intersecting the first direction D1.

FIG. 10 is a schematic cross-sectional view illustrating the semiconductor light emitting device according to the second embodiment.

FIG. 10 shows a portion AP of FIG. 8A on an enlarged scale.

As shown in FIG. 10, in the semiconductor light emitting device 120, a level difference is formed by the insulating layer 83. The first insulating layer 81 relaxes this level difference.

That is, the semiconductor light emitting device 120 includes the base body 70, the first semiconductor layer 10, the third insulating layer 83, the first insulating layer 81, and the second insulating layer 82.

The third insulating layer 83 is provided between a part (second semiconductor region 10q) of the first semiconductor layer 10 and the base body 70.

The first insulating layer 81 is provided between the third insulating layer 83 and the base body 70 and between another part (first semiconductor region 10p) of the first semiconductor layer 10 and the base body 70.

The second insulating layer 82 is provided between the first insulating layer 81 and the base body 70.

Also in this case, the first insulating layer 81 has a thickness (first thickness t1) at a first position p1 where the first insulating layer 81 overlaps with the third insulating layer 83 in a first direction D1 directed from the base body 70 to the first semiconductor layer 10. The first insulating layer 81 has a thickness (second thickness t2) at a second position p2 where the first insulating layer 81 does not overlap with the third insulating layer 83 in the first direction D1. The first thickness t1 is smaller than the second thickness t2.

The second insulating layer 82 has a thickness (third thickness t3) at the first position p1. The second insulating layer 82 has a thickness (fourth thickness t4) at the second position p2. An absolute value (second absolute value) of a difference between the third thickness t3 and the fourth thickness t4 is smaller than an absolute value (first absolute value) of a difference between the first thickness t1 and the second thickness t2.

In the semiconductor light emitting device 120, a level difference due to the third insulating layer 83 is relaxed by the first insulating layer 81. Due to this, in the second insulating layer 82, the generation of the above-mentioned discontinuous portion is suppressed. Accordingly, in the embodiment, high insulation performance is obtained. Thus, a high breakdown voltage is obtained.

The second absolute value is smaller than the thickness t83 of the third insulating layer 83. The second absolute value is ½ or less of the thickness t83 of the third insulating layer 83. The second absolute value is preferably more than 0 times and ⅕ times or less of the thickness t83 of the third insulating layer 83.

An absolute value of a difference between the first absolute value and the second absolute value is preferably ½ times or more and 1.2 times or less of the thickness t83 of the third insulating layer 83. The first absolute value is preferably ½ times or more and 1.2 times or less of the thickness t83 of the third insulating layer 83.

In the semiconductor light emitting device 120, the first conductive layer 50 (second metal layer 52) is provided so as to cover the level difference due to the third insulating layer 83. A surface of the second metal layer 52 in contact with the first insulating layer 81 has a level difference which reflects the level difference in the third insulating layer 83. The first insulating layer 81 relaxes this level difference in the second metal layer 52. In this manner, between the layer (third insulating layer 83) causing a level difference and the first insulating layer 81, another layer (the second metal layer 52) may be provided.

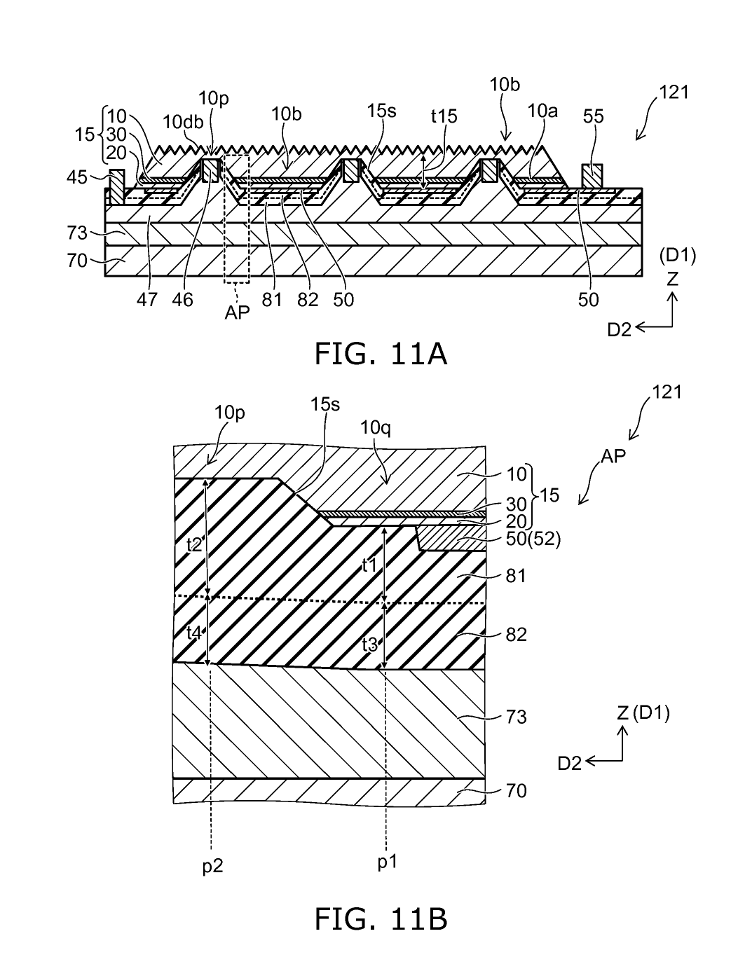

FIG. 11A and FIG. 11B are schematic cross-sectional views illustrating another semiconductor light emitting device according to the second embodiment.

FIG. 11B shows a portion AP of FIG. 11A on an enlarged scale.

Also another semiconductor light emitting device 121 according to the embodiment includes a base body 70, a first semiconductor layer 10, a second semiconductor layer 20, a third semiconductor layer 30, a first conductive layer 50, a first insulating layer 81, and a second insulating layer 82. In the semiconductor light emitting device 121, the following configuration is different from that of the semiconductor light emitting device 120. Other than this, the configuration described with respect to the semiconductor light emitting device 120 and the semiconductor light emitting device 110 can be applied.

In the semiconductor light emitting device 121, an electrode 46 and a metal layer 47 are provided. The electrode 46 is provided between a first semiconductor region 10p and the base body 70. The electrode 46 is electrically connected to the first semiconductor region 10p.

The first insulating layer 81 is provided between a side surface 15s of a stacked body 15 and the base body 70, between the second semiconductor layer 20 and the base body 70, and between the first conductive layer 50 and the base body 70. The second insulating layer 82 is provided between the first insulating layer 81 and the base body 70.

The metal layer 47 is provided between the electrode 46 and the base body 70 and between the second insulating layer 82 and the base body 70. The metal layer 47 is connected to the electrode 46. A part of the metal layer 47 is provided between a first pad 45 and the base body 70.

In this example, a metal layer 73 (bonding layer) is provided. The metal layer 73 is provided between the metal layer 47 and the base body 70.

Also in this case, a first thickness t1 of the first insulating layer 81 at a first position p1 where the first insulating layer 81 overlaps with a second semiconductor region 10q in the first direction D1 is smaller than a second thickness t2 of the first insulating layer 81 at a second position p2 where the first insulating layer 81 overlaps with a first semiconductor region 10p in the first direction D1.

An absolute value (second absolute value) of a difference between a third thickness t3 of the second insulating layer 82 at the first position p1 and a fourth thickness t4 of the second insulating layer 82 at the second position p2 is smaller than an absolute value (first absolute value) of a difference between the first thickness t1 and the second thickness t2. Also in this case, high insulation performance is obtained, and thus, a high breakdown voltage is obtained.

In the semiconductor light emitting device 121, the second absolute value is smaller than a level difference s15 in the stacked body 15. The second absolute value is ½ or less of the level difference s15 in the stacked body. The second absolute value is preferably more than 0 times and ⅕ times or less of the level difference s15 in the stacked body 15. An absolute value of a difference between the first absolute value and the second absolute value is preferably ½ times or more and 1.2 times or less of the level difference s15 in the stacked body 15. The first absolute value is preferably ½ times or more and 1.2 times or less of the level difference s15 in the stacked body 15.

In the above-mentioned respective embodiments, a difference in the thickness of the first insulating layer 81 is larger than a difference in the thickness of the second insulating layer 82. This difference will be described below.

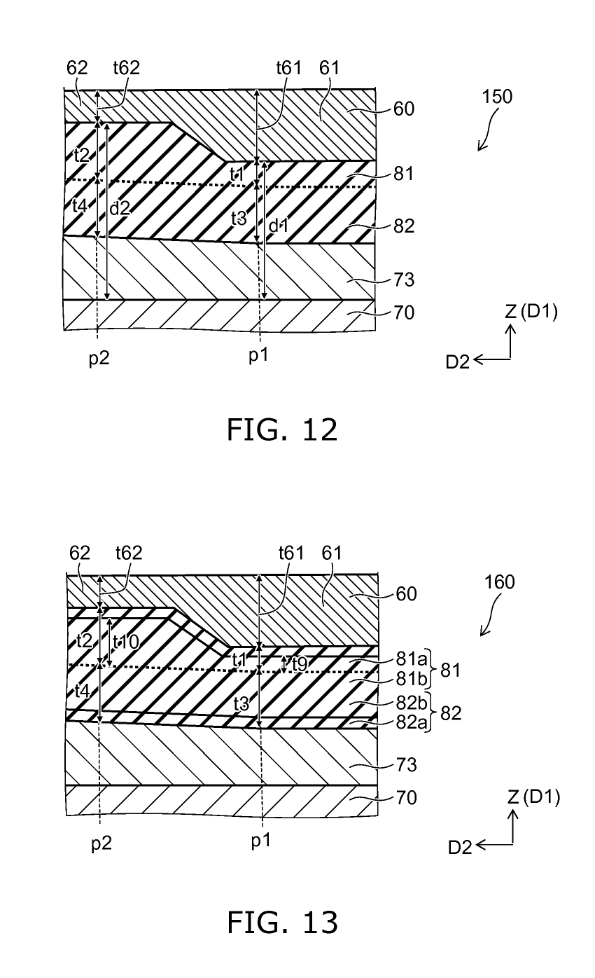

FIG. 12 is a schematic cross-sectional view illustrating a semiconductor light emitting device according to the embodiment.

As shown in FIG. 12, a semiconductor light emitting device 150 according to the embodiment includes a base body 70, a first layer 60, a first insulating layer 81, and a second insulating layer 82.

The first layer 60 is spaced apart from the base body 70 in the first direction D1. The first layer 60 includes a first region 61 and a second region 62. The second region 62 is juxtaposed with the first region 61 in a direction intersecting the first direction D1.

A distance (first distance d1) between the first region 61 and the base body 70 is shorter than a distance (second distance d2) between the second region 62 and the base body 70. For example, the first region 61 has a length t61 (thickness) along the first direction D1. The second region 62 has a length t62 (thickness) along the first direction D1. The length t61 (thickness) is larger than the length t62 (thickness). The first layer 60 may be a stacked film which includes multiple films.

The first insulating layer 81 is provided between the first region 61 and the base body 70 and between the second region 62 and the base body 70.

The second insulating layer 82 is provided between the first insulating layer 81 and the base body 70.

A first thickness t1 of the first insulating layer 81 at a first position p1 where the first insulating layer 81 overlaps with the first region 61 in the first direction D1 is smaller than a second thickness t2 of the first insulating layer 81 at a second position p2 where the first insulating layer 81 overlaps with the second region 62 in the first direction D1.

A second absolute value of a difference between a third thickness t3 of the second insulating layer 82 at the first position p1 and a fourth thickness t4 of the second insulating layer 82 at the second position p2 is smaller than a first absolute value of a difference between the first thickness t1 and the second thickness t2.

Also in the semiconductor light emitting device 150, a level difference in the first layer 60 is relaxed by the first insulating layer 81. Due to this, in the second insulating layer 82, the generation of the above-mentioned discontinuous portion is suppressed. Accordingly, in the embodiment, high insulation performance is obtained. Thus, a high breakdown voltage is obtained.

In the semiconductor light emitting device 150, the second absolute value is smaller than the level difference in the first layer 60 (an absolute value of a difference between the first distance d1 and the second distance d2). The second absolute value is ½ or less of the level difference in the first layer 60. The second absolute value is preferably more than 0 times and ⅕ times or less of the level difference in the first layer 60. An absolute value of a difference between the first absolute value and the second absolute value is preferably ½ times or more and 1.2 times or less of the level difference in the first layer 60. The first absolute value is preferably ½ times or more and 1.2 times or less of the level difference in the first layer 60.

In the semiconductor light emitting devices 110 and 111 described above, for example, the first layer 60 and the first region 61 correspond to a portion where the second semiconductor layer 20 and the first conductive layer 50 are stacked. The second region 62 corresponds to the second semiconductor layer 20 (a portion where the first conductive layer 50 is not stacked). In the semiconductor light emitting devices 110 and 111, the first region 61 may include the first metal layer 51. In the semiconductor light emitting devices 110 and 111, the first region 61 may include the second metal layer 52.

In the semiconductor light emitting device 120 described above, for example, the first region 61 corresponds to the second semiconductor region 10q of the first semiconductor layer 10, the second semiconductor layer 20, and the third semiconductor layer 30 (see FIG. 8B). The second region 62 corresponds to the first semiconductor region 10p. In the semiconductor light emitting device 120, for example, the first region 61 may correspond to a portion where the second semiconductor layer 20 and the third insulating layer 83 are stacked, and the second region 62 may correspond to the second semiconductor layer 20 (a portion where the third insulating layer 83 is not stacked) (see FIG. 10).

In the semiconductor light emitting device 121 described above, for example, the first region 61 corresponds to the second semiconductor region 10q, the second semiconductor layer 20, and the third semiconductor layer 30. The second region 62 corresponds to the first semiconductor region 10p. In the semiconductor light emitting device 121, for example, the first region 61 may correspond to the second semiconductor layer 20 and the first conductive layer 50, and the second region 62 may correspond to the second semiconductor layer 20 (a portion where the first conductive layer 50 is not stacked).

Further, in the embodiment, the first region 61 may correspond to at least either of the second conductive layer 42 and the electrode 46, and the first semiconductor layer 10. The second region 62 may correspond to the first semiconductor layer 10 (a portion where the second conductive layer 42 or the electrode 46 is not stacked).

As the first layer 60, any of a conductive layer, a semiconductor layer, and an insulating layer is used. Between the first layer 60 and the first insulating layer 81, another layer may be provided.

### Third Embodiment

FIG. 13 is a schematic cross-sectional view illustrating a semiconductor light emitting device according to a third embodiment.

As shown in FIG. 13, in a semiconductor light emitting device 160 according to the embodiment, a first insulating layer 81 includes a first film 81a and a second film 81b. In this example, a second insulating layer 82 includes a third film 82a and a fourth film 82b.

The first film 81a includes silicon oxide. The second film 81b is provided between the first film 81a and the second insulating layer 82. The second film 81b includes at least one of silicon nitride and aluminum oxide.

The third film 82a includes silicon oxide. The fourth film 82b is provided between the third film 82a and the first insulating layer 81. That is, the fourth film 82b is provided between the third film 82a and the second film 81b. The fourth film 82b includes at least one of silicon nitride and aluminum oxide.

For example, the second film 81b and the fourth film 82b includes silicon nitride. In this case, to the first insulating layer 81 and the second insulating layer 82, for example, a configuration of silicon oxide/silicon nitride/silicon oxide (for example, SiO₂/SiNₓ/SiO₂) is applied.

For example, the second film 81b and the fourth film 82b includes aluminum oxide. In this case, to the first insulating layer 81 and the second insulating layer 82, for example, a configuration of silicon oxide/aluminum oxide/silicon oxide (for example, SiO₂/Al₂O₃/SiO₂) is applied.

Further, between two silicon oxide films, a film including at least one of silicon nitride and aluminum oxide may be provided.

According to an experiment conducted by the inventor, it was found that a high breakdown voltage is obtained in the case of using as the insulating layer, a stacked film (a stacked film of different materials) of silicon oxide/silicon nitride/silicon oxide, silicon oxide/aluminum oxide/silicon oxide, or the like as compared with the case of using as the insulating layer, for example, a single layer of silicon oxide or a stacked film of a silicon oxide film.

For example, a breakdown voltage in a single film of SiO₂ (having a thickness of about 4 μm) is from 700 V to 1,100 V.

On the other hand, an AC breakdown voltage in a stacked film of SiO₂ (having a thickness of 0.05 μm)/SiNₓ (having a thickness of about 4 μm)/SiO₂ (having a thickness of 0.05 μm) is from about 1,400 V to 2,100 V. Also in a stacked film of silicon oxide/aluminum oxide/silicon oxide, a similar high breakdown voltage is obtained.

For example, according to the Poole-Frenkel effect, a leakage current value in a dielectric film when a high voltage is applied depends on the thickness of the dielectric film, the relative dielectric constant of a dielectric body, and the barrier height of the dielectric body. The barrier height strongly depends on the quality of the dielectric body. If the quality is low, an impurity level like a subband is liable to be formed in the dielectric body, and the barrier height is decreased. As a result, a leakage current is easy to flow.

In silicon oxide, the barrier height is high, and therefore, a leakage current is difficult to flow. Therefore, the breakdown voltage depends on breakdown. On the other hand, in silicon nitride or aluminum oxide, the barrier height is low, and a leakage current is easy to flow. Therefore, the concentration of the electric field is suppressed, and thus, breakdown is difficult to occur. In this manner, characteristics are different between silicon oxide and silicon nitride. Further, characteristics are different between silicon oxide and aluminum oxide.

In the embodiment, the first film 81a including silicon oxide and the second film 81b including silicon nitride and aluminum oxide are combined. According to this, a high breakdown voltage can be obtained while suppressing breakdown by a moderate leakage current.

In this manner, in the embodiment, by using the above-mentioned stacked film including different materials, a further higher breakdown voltage is obtained.

The first insulating layer 81 and the second insulating layer 82 in the semiconductor light emitting device 160 are formed, for example, as follows.

On a surface having a level difference formed thereon of the first layer 60, as the first film 81a, a silicon oxide film (having a thickness of, for example, 0.05 μm) is formed. On the first film 81a, a silicon nitride film (having a thickness of, for example, 3 μm) which becomes the second film 82a is formed. The surface of this silicon nitride film is flattened. In this flattening, for example, a method using the sacrifice film 80r and etching back described above is used. CMP may be performed. The thickness of the flattened silicon nitride film is about 2 μm. Thereafter, a silicon nitride film (having a thickness of, for example, 2 μm) which becomes the fourth film 82b is formed. On the fourth film 82b, a silicon oxide film (having a thickness of, for example, 0.05 μm) which becomes the third film 82a is formed.

In the semiconductor light emitting device 160, a ninth thickness t9 of the second film 81b at a first position p1 is smaller than a tenth thickness t10 of the second film 81b at a second position p2.

For example, a second absolute value (an absolute value of a difference between the third thickness t3 and the fourth thickness t4) is smaller than an absolute value of a difference between the ninth thickness t9 and the tenth thickness t10.

The level difference is relaxed by the second film 81b. Due to this, in the second insulating layer 82, the generation of the above-mentioned discontinuous portion is suppressed. Accordingly, in the embodiment, high insulation performance is obtained. Thus, a high breakdown voltage is obtained.

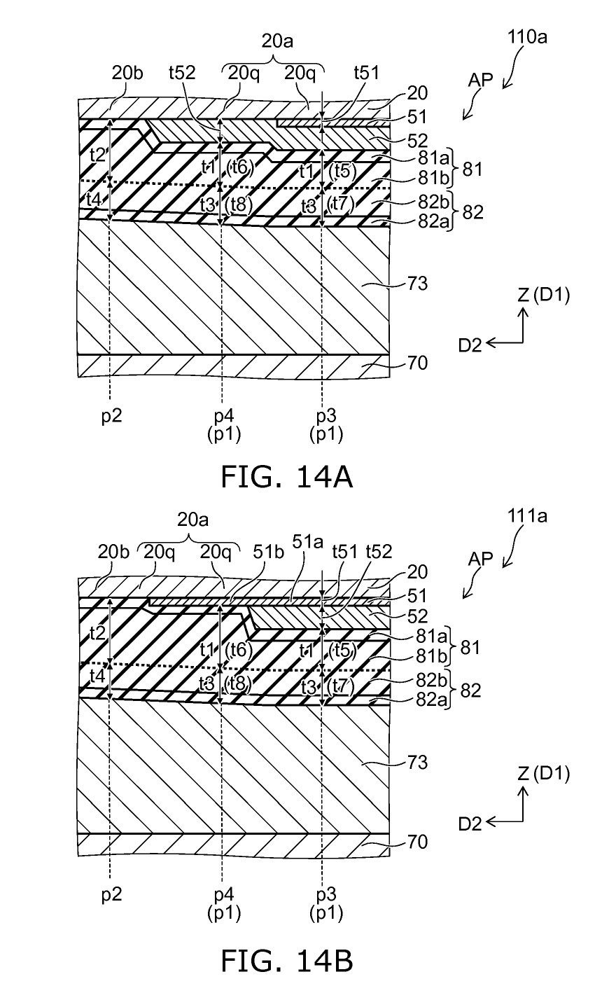

FIG. 14A and FIG. 14B are schematic cross-sectional views illustrating other semiconductor light emitting devices according to the third embodiment.

As shown in FIG. 14A and FIG. 14B, in semiconductor light emitting devices 110a and 111a, a first film 81a and a second film 81b are provided in the first insulating layer 81 in each of the semiconductor light emitting devices 110 and 111 described above. In the second insulating layer 82, a third film 82a and a fourth film 82b are provided.

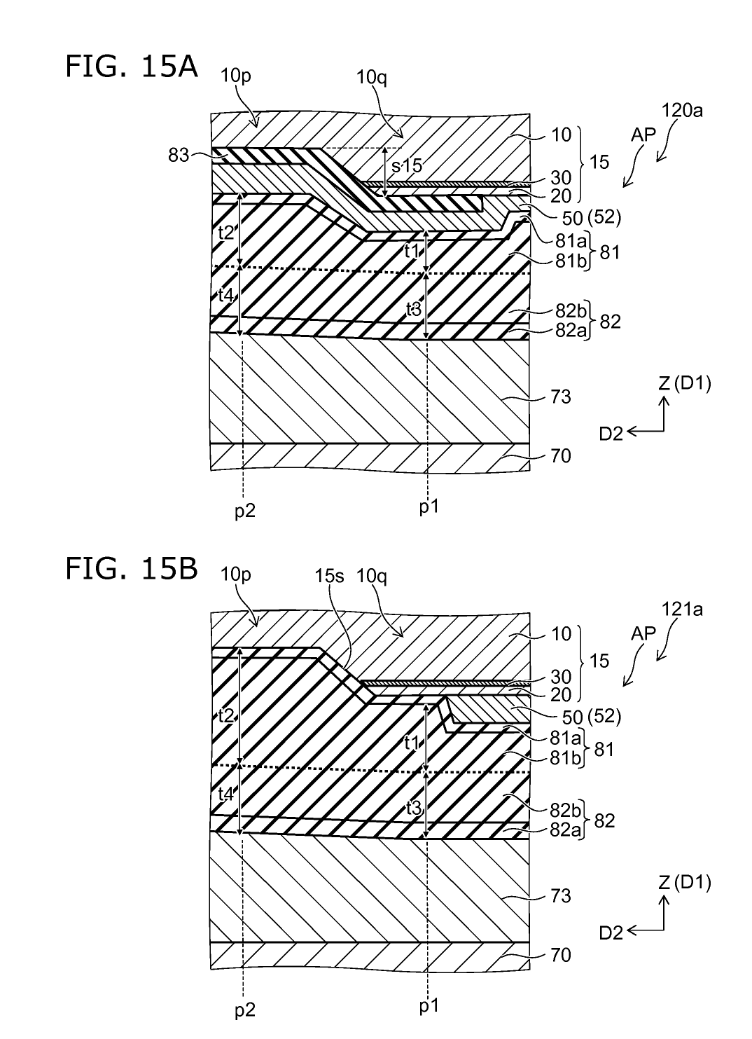

FIG. 15A and FIG. 15B are schematic cross-sectional views illustrating other semiconductor light emitting devices according to the third embodiment.

As shown in FIG. FIG. 15A and FIG. 15B, in semiconductor light emitting devices 120a and 121a, a first film 81a and a second film 81b are provided in the first insulating layer 81 in each of the semiconductor light emitting devices 120 and 121 described above. In the second insulating layer 82, a third film 82a and a fourth film 82b are provided.

Also in the semiconductor light emitting devices 110a, 111a, 120a, and 121a, by using the above-mentioned stacked film including different materials, a further higher breakdown voltage is obtained.

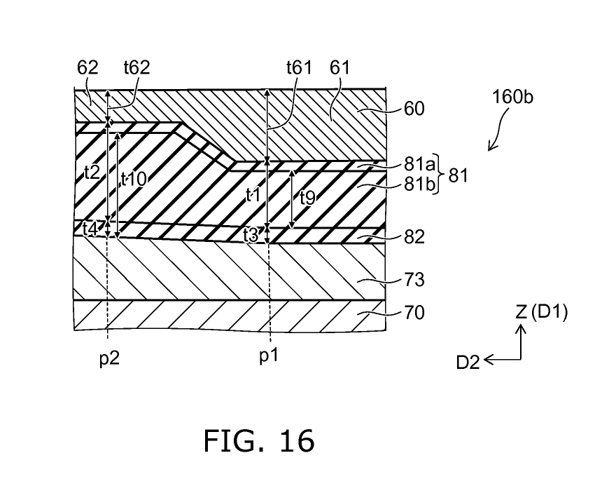

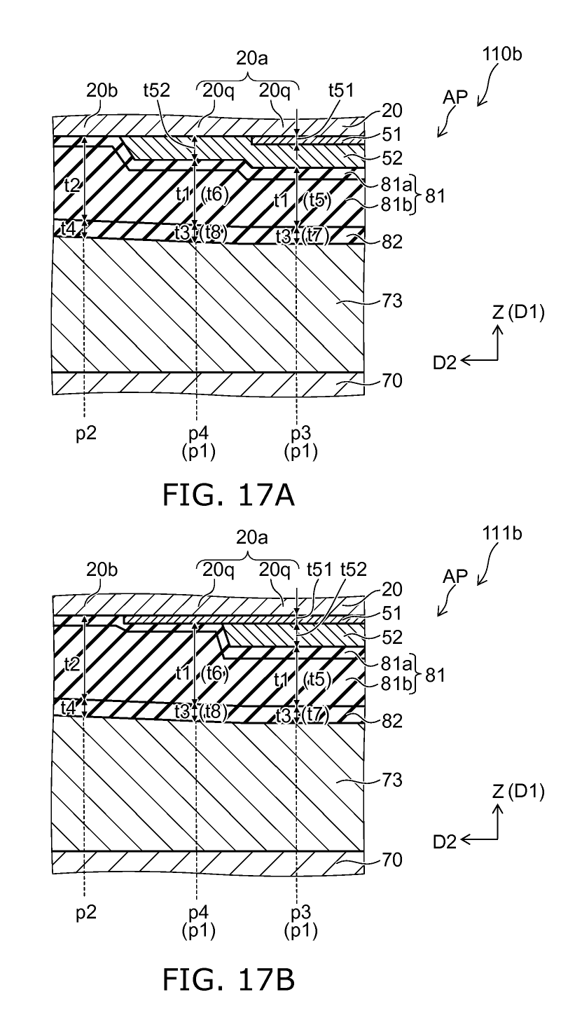

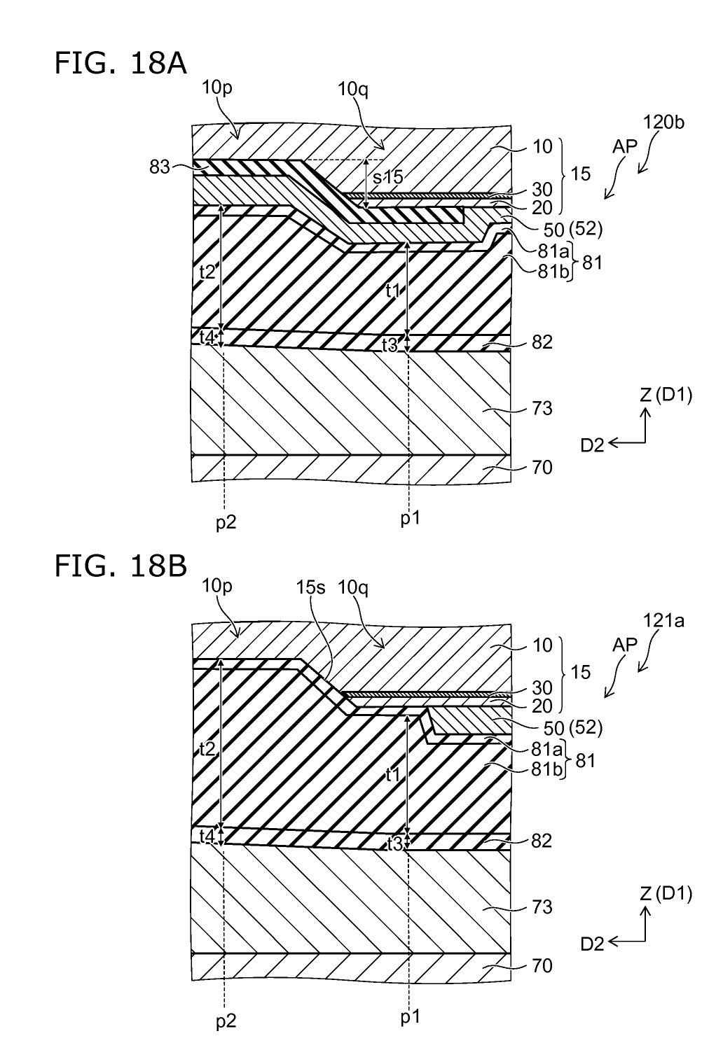

FIG. 16, FIG. 17A, FIG. 17B, FIG. 18A, and FIG. 18B are schematic cross-sectional views illustrating other semiconductor light emitting devices according to the third embodiment.

As shown in these drawings, semiconductor light emitting devices 160b, 110b, 111b, 120b, and 121b, the second insulating layer 82 is a single-layered film. Other than this, the configurations are the same as those of the semiconductor light emitting devices 160, 110a, 111a, 120a, and 121a, respectively. Also in the semiconductor light emitting devices 160b, 110b, 111b, 120b, and 121b, a high breakdown voltage is obtained.

### Fourth Embodiment

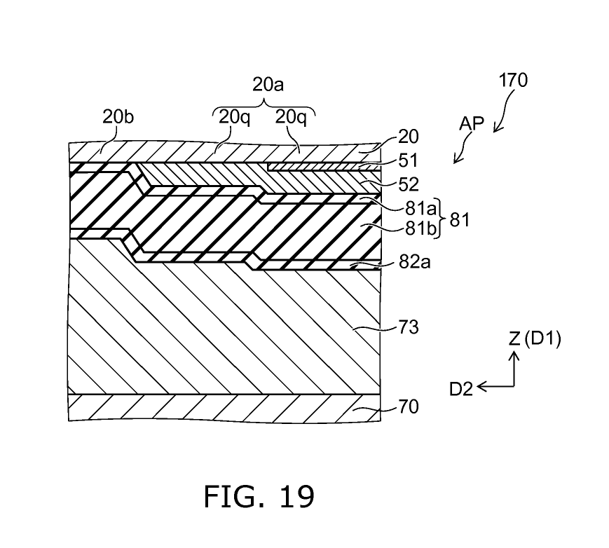

FIG. 19 is a schematic cross-sectional view illustrating a semiconductor light emitting device according to a fourth embodiment.

As shown in FIG. 19, in a semiconductor light emitting device 170 according to the embodiment, at the positions of the first insulating layer 81 and the second insulating layer 82 described above, a first film 81a, a second film 81b, and a third film 82a, each of which is an insulating film, are provided. Then, the sectional shapes of these films follow the sectional shape of the first conductive layer 50. That is, a level difference in the first conductive layer 50 is reflected by these insulating films.

The first film 81a includes silicon oxide. The second film 81b is provided between the first film 81a and the third film 82a. The second film 81b includes at least one of silicon nitride and aluminum oxide. On the other hand, the second insulating layer includes, for example, silicon oxide.

That is, a configuration of silicon oxide/silicon nitride/silicon oxide or silicon oxide/aluminum oxide/silicon oxide is applied. As described above, in these stacked films, a high breakdown voltage is obtained. According to the semiconductor light emitting device 170, a semiconductor light emitting device capable of improving the breakdown voltage can be provided. Between two silicon oxide films, a film including at least one of silicon nitride and aluminum oxide may be provided.

According to the above-mentioned embodiment, a semiconductor light emitting device capable of improving the breakdown voltage can be provided.

Incidentally, in the specification, the “nitride semiconductor” encompasses semiconductors having all the compositions obtained by changing the compositional ratios x, y, and z within the respective ranges in the chemical formula: BₓIn_{y}Al_{z}Ga_{1-x-y-z}N (0≦x≦1, 0≦y≦1, 0≦z≦1, x+y+z≦1). Further, semiconductors further including a V group element other than N (nitrogen) in the above chemical formula, semiconductors further including any of various elements to be added for controlling various physical properties such as a conductivity type, and semiconductors further including any of various elements to be contained unintentionally are also encompassed in the “nitride semiconductor”.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor light emitting devices such as a first semiconductor layer, a second semiconductor layer, a third semiconductor layer, a first conductive layer, a second conductive layer, a first pad, a second pad, metal layers, insulating layers, metal films, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor light emitting devices practicable by an appropriate design modification by one skilled in the art based on the semiconductor light emitting devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device, comprising:
a base body;
a first semiconductor layer including a region of a first conductivity type;
a second semiconductor layer of a second conductivity type, the second semiconductor layer being provided between the first semiconductor layer and the base body;
a third semiconductor layer provided between the first semiconductor layer and the second semiconductor layer;
a first conductive layer provided between a part of the second semiconductor layer and the base body, the first conductive layer being electrically connected to the second semiconductor layer;
a first insulating layer provided between another part of the second semiconductor layer and the base body and between the first conductive layer and the base body; and
a second insulating layer provided between the first insulating layer and the base body,
a first thickness of the first insulating layer at a first position being smaller than a second thickness of the first insulating layer at a second position, the first insulating layer overlapping the first conductive layer at the first position in a first direction from the second semiconductor layer toward the first semiconductor layer, the first insulating layer not overlapping the first conductive layer at the second position in the first direction, and
a second absolute value of a difference between a third thickness of the second insulating layer at the first position and a fourth thickness of the second insulating layer at the second position being smaller than a first absolute value of a difference between the first thickness and the second thickness.

2. The device according to claim 1, wherein the second absolute value is smaller than a thickness of the first conductive layer.

3. The device according to claim 1, wherein the second absolute value is not more than ½ a thickness of the first conductive layer.

4. The device according to claim 1, wherein an absolute value of a difference between the first absolute value and the second absolute value is not less than ½ times and not more than 1.2 times a thickness of the first conductive layer.

5. The device according to claim 1, wherein
the device further includes
a first pad, and
a second pad, and
the first semiconductor layer is disposed between the first pad and the third semiconductor layer, and the first pad is electrically connected to the first semiconductor layer,
a part of the first conductive layer is disposed between the part of the second semiconductor layer and the base body,
another part of the first conductive layer is disposed between the second pad and the base body, and
the second pad is electrically connected to the another part of the conductive layer.

6. The device according to claim 5, wherein a distance between the first pad and the first conductive layer is not less than 1.5 μm and not more than 30 μm.

7. The device according to claim 5, wherein at least a part of the second pad overlaps at least a part of a stacked body including the first semiconductor layer, the third semiconductor layer, and the second semiconductor layer in a direction intersecting the first direction.

8. The device according to claim 5, wherein
the first conductive layer includes a first metal layer and a second metal layer,
the first metal layer is provided between a part of the second metal layer and the second semiconductor layer,
a fifth thickness of the first insulating layer at a third position is smaller than a sixth thickness of the first insulating layer at a fourth position, the first insulating layer overlaps the first metal layer at the third position in the first direction, the first insulating layer overlaps the first conductive layer but does not overlap the first metal layer at the fourth position in the first direction, and
a fourth absolute value of a difference between a seventh thickness of the second insulating layer at the third position and an eighth thickness of the second insulating layer at the fourth position is smaller than a third absolute value of a difference between the fifth thickness and the sixth thickness.

9. The device according to claim 8, wherein the fourth absolute value is smaller than a thickness of the first metal layer.

10. The device according to claim 5, wherein
the first conductive layer includes a first metal layer and a second metal layer,
a part of the first metal layer is provided between the second metal layer and the second semiconductor layer,
a fifth thickness of the first insulating layer at a third position is smaller than a sixth thickness of the first insulating layer at a fourth position, the first insulating layer overlaps the part of the first metal layer at the third position in the first direction, the first insulating layer overlaps the first metal layer but does not overlap the second metal layer at the fourth position in the first direction, and
a fourth absolute value of a difference between a seventh thickness of the second insulating layer at the third position and an eighth thickness of the second insulating layer at the fourth position is smaller than a third absolute value of a difference between the fifth thickness and the sixth thickness.

11. The device according to claim 10, wherein the fourth absolute value is smaller than a thickness of the second metal layer.

12. The device according to claim 8, wherein an absolute value of a difference between the third absolute value and the fourth absolute value is not less than ½ times and not more than 1.2 times a thickness of the first metal layer.

13. The device according to claim 8, wherein
the part of the first conductive layer includes the first metal layer and the part of the second metal layer, and
the another part of the first conductive layer includes another part of the second metal layer.

14. A semiconductor light emitting device, comprising:
a base body;
a first semiconductor layer spaced apart from the base body in a first direction, the first semiconductor layer including a first semiconductor region and a second semiconductor region juxtaposed with the first semiconductor region in a direction intersecting the first direction, and also including a region of a first conductivity type;
a second semiconductor layer of a second conductivity type, the second semiconductor layer being provided between the second semiconductor region and the base body;
a third semiconductor layer provided between the first semiconductor layer and the second semiconductor layer;
a first insulating layer provided between the first semiconductor region and the base body and between the second semiconductor layer and the base body; and
a second insulating layer provided between the first insulating layer and the base body,
a first thickness of the first insulating layer at a first position being smaller than a second thickness of the first insulating layer at a second position, the first insulating layer overlapping the second semiconductor region at the first position in the first direction, the first insulating layer overlapping the first semiconductor region at the second position in the first direction, and
a second absolute value of a difference between a third thickness of the second insulating layer at the first position and a fourth thickness of the second insulating layer at the second position being smaller than a first absolute value of a difference between the first thickness and the second thickness.

15. The device according to claim 14, wherein
the device further includes
a first pad,
a second pad,
a first conductive layer, and
a second conductive layer, and
a part of the second conductive layer is disposed between the base body and the first semiconductor region,
the part of the second conductive layer is electrically connected to the first semiconductor region,
another part of the second conductive layer is disposed between the first pad and the base body,
the first pad is electrically connected to the another part of the second conductive layer,
a part of the first conductive layer is disposed between the second conductive layer and the base body,
another part of the first conductive layer is disposed between the second pad and the base body, and
the second pad is electrically connected to the another part of the first conductive layer.

16. The device according to claim 14, wherein
the first semiconductor layer has a first surface on a side of the third semiconductor layer and a second surface on an opposite side to the first surface, and
a distance between the first conductive layer and the second surface is not less than 1.5 μm and not more than 30 μm.

17. The device according to claim 14, wherein at least a part of the first pad overlaps at least a part of a stacked body including the first semiconductor layer, the third semiconductor layer, and the second semiconductor layer in a direction intersecting the first direction.

18. A semiconductor light emitting device, comprising:
a base body;
a first layer spaced apart from the base body in a first direction, the first layer including a first region and a second region juxtaposed with the first region in a direction intersecting the first direction, a distance between the first region and the base body being shorter than a distance between the second region and the base body;
a first insulating layer provided between the first region and the base body and between the second region and the base body; and
a second insulating layer provided between the first insulating layer and the base body,
a first thickness of the first insulating layer at a first position being smaller than a second thickness of the first insulating layer at a second position, the first insulating layer overlapping the first region at the first position in a first direction from the base body toward the first layer, the first insulating layer overlapping the second region at the second position in the first direction, and
a second absolute value of a difference between a third thickness of the second insulating layer at the first position and a fourth thickness of the second insulating layer at the second position being smaller than a first absolute value of a difference between the first thickness and the second thickness.

19. The device according to claim 1, wherein
the first insulating layer includes
a first film including silicon oxide, and
a second film provided between the first film and the second insulating layer and including at least one of silicon nitride and aluminum oxide, and
the second insulating layer includes
a third film including silicon oxide, and
a fourth film provided between the third film and the first insulating layer and including at least one of silicon nitride and aluminum oxide.

20. The device according to claim 19, wherein a ninth thickness of the second film at the first position is smaller than a tenth thickness of the second film at the second position.
